(19) United States
(12) Patent Application Publication
(10) Pub. No.: US 2026/0019038 A1
(43) Pub. Date: Jan. 15, 2026

(54) TRACKER SYSTEM AND TRACKER MODULE

(71) Applicant: Murat Manufacturing Co., Ltd., Nagaokakyo-shi (JP)

(72) Inventors: Takeshi KOGURE, Nagaokakyo-shi (JP); Hiroyuki NAGAMORI, Nagaokakyo-shi (JP)

(21) Appl. No.: 19/338,069

(22) Filed: Sep. 24, 2025

Related U.S. Application Data
(63) Continuation of application No. PCT/JP2024/006924, filed on Feb. 27, 2024.

(30) Foreign Application Priority Data
Mar. 28, 2023 (JP) 2023-051719

(51) Int. Cl. H03F 1/02; H02M 3/07; H03F 3/24

(52) U.S. Cl. CPC H03F 1/0227; H02M 3/07; H03F 3/245; H03F 2200/102; H03F 2200/105; H03F 2200/451

(57) ABSTRACT

A tracker system is provided that includes a first integrated circuit disposed in or on a module laminate and a second integrated circuit disposed to be separate from the module laminate. The first integrated circuit includes switches of a switched-capacitor circuit and switches of first and second supply modulators. The second integrated circuit includes switches of a third supply modulator. The switched-capacitor circuit generates multiple discrete voltages. The first supply modulator outputs at least one of the discrete voltages to a first power amplifier. The second supply modulator outputs at least one of the discrete voltages to a second power amplifier. The third supply modulator outputs at least one of the discrete voltages to a third power amplifier. The first and second power amplifiers are connected to a primary antenna. The third power amplifier is connected to a secondary antenna.

### CROSS REFERENCE TO RELATED APPLICATIONS

This application is a continuation of International Application No. PCT/JP2024/006924, filed Feb. 27, 2024, which claims priority to Japanese Patent Application No. 2023-051719, filed Mar. 28, 2023, the entire contents of each of which are hereby incorporated by reference in their entirety.

### TECHNICAL FIELD

The present disclosure relates to a tracker system and a tracker module.

### BACKGROUND

These days, with the application of an envelope tracking (ET) technology to a power amplifier circuit, the power-added efficiency is being improved. For example, U.S. Pat. No. 8,829,993 discloses a digital envelope tracking (D-ET) technology for selectively supplying multiple discrete voltages based on an envelope signal.

### Summary of Disclosure

3GPP (registered trademark) (3rd Generation Partnership Project) has been examining simultaneous transmission of three radio-frequency signals (3Tx) in user equipment (UE) in a mobile communication system. In a 3Tx-support D-ET system and a 3Tx-support D-ET module, the module may become larger.

In view of foregoing, the exemplary aspects of the present disclosure provides a tracker system and a tracker module that can reduce the size of a 3Tx-support D-ET module.

In an exemplary aspect, a tracker system is provided that includes a module laminate, at least one first integrated circuit disposed in or on the module laminate, and at least one second integrated circuit disposed to be separate from the module laminate. The at least one first integrated circuit includes at least a first switch in a switched-capacitor circuit, at least a second switch in a first supply modulator, and at least a third switch in a second supply modulator. The at least one second integrated circuit includes at least a fourth switch in a third supply modulator. The switched-capacitor circuit is configured to generate multiple discrete voltages. The first supply modulator is configured to selectively output at least one discrete voltage of the multiple discrete voltages to a first power amplifier connected to a primary antenna. The second supply modulator is configured to selectively output at least one discrete voltage of the multiple discrete voltages to a second power amplifier connected to the primary antenna. The third supply modulator is configured to selectively output at least one discrete voltage of the multiple discrete voltages to a third power amplifier connected to a secondary antenna.

In another exemplary aspect, a tracker module is provided that includes a module laminate, at least one integrated circuit disposed in or on the module laminate, a first external connection terminal, a second external connection terminal, and multiple third external connection terminals. The first, second, and third external connection terminals are disposed in or on the module laminate. The at least one integrated circuit includes at least a first switch included in a switched-capacitor circuit, at least a second switch included in a first supply modulator, and at least a third switch included in a second supply modulator. The switched-capacitor circuit is configured to generate multiple discrete voltages and output the generated discrete voltages to the first supply modulator, the second supply modulator, and the multiple third external connection terminals. The first supply modulator is configured to selectively output at least one discrete voltage of the multiple discrete voltages to the first external connection terminal. The second supply modulator is configured to selectively output at least one discrete voltage of the multiple discrete voltages to the second external connection terminal. The first external connection terminal is connected to a first power amplifier that is connected to a primary antenna. The second external connection terminal is connected to a second power amplifier that is connected to the primary antenna. The multiple third external connection terminals are selectively connected to a third power amplifier that is connected to a secondary antenna.

According to some exemplary aspects of the present disclosure, it is possible to reduce the size of a 3Tx-support D-ET module.

### BRIEF DESCRIPTION OF DRAWINGS

FIG. 1A is a graph illustrating an example of the transition of a power supply voltage in an APT (Average Power Tracking) mode.

FIG. 1B is a graph illustrating an example of the transition of a power supply voltage in an A-ET (Analog Envelope Tracking) mode.

FIG. 1C is a graph illustrating an example of the transition of a power supply voltage in a D-ET mode.

FIG. 2 is a circuit diagram of a communication device according to an exemplary embodiment.

FIG. 3 is a circuit diagram of a pre-regulator circuit according to the exemplary embodiment.

FIG. 4 is a circuit diagram of a switched-capacitor circuit according to the exemplary embodiment.

FIG. 5A is a circuit diagram of a supply modulator according to the exemplary embodiment.

FIG. 5B is a circuit diagram of a supply modulator according to the exemplary embodiment.

FIG. 5C is a circuit diagram of a supply modulator according to the exemplary embodiment.

FIG. 6 is a circuit diagram of a digital control circuit according to the exemplary embodiment.

FIG. 7 illustrates an implementation example of the communication device according to the exemplary embodiment.

FIG. 8 is a flowchart illustrating a voltage supply method according to the exemplary embodiment.

FIG. 9 is a flowchart illustrating the voltage supply method according to the exemplary embodiment.

### DETAILED DESCRIPTION OF EMBODIMENTS

Exemplary embodiments of the disclosure will be described below in detail with reference to the drawings. All the embodiments described below illustrate general or specific examples. Numerical values, configurations, materials, elements, and positions and connection states of the elements illustrated in the following embodiments are only examples and are not intended to limit the exemplary aspects of the present disclosure.

The drawings are only schematically shown and are not necessarily precisely illustrated. For the sake of representing the disclosure, according to the necessity, the drawings are illustrated in an exaggerated manner or with omissions or the ratios of elements in the drawings are adjusted. The shapes, positional relationships, and ratios of elements in the drawings may be different from those of the actual elements. In the individual drawings, substantially identical elements are designated by like reference numeral, and it is possible that an explanation of such elements be not repeated or be merely simplified.

In the drawings, the x axis and the y axis are axes which are perpendicular to each other on a plane parallel with the main surfaces of a module laminate. More specifically, when the module laminate has a rectangular shape in a plan view, the x axis is parallel with a first side of the module laminate, while the y axis is parallel with a second side, which is perpendicular to the first side, of the module laminate. The z axis is an axis perpendicular to the main surfaces of the module laminate. The positive direction of the z axis is the upward direction, while the negative direction of the z axis is the downward direction.

In the following explanation of the circuit configurations, the phrase “A is connected to B” includes, not only the meaning that A is directly connected to B using a connection terminal and/or a wiring conductor, but also the meaning that A is electrically connected to B via another circuit element. The phrase “A is directly connected to B” can mean that A is directly connected to B using a connection terminal and/or a wiring conductor without another circuit element interposed between A and B. The phrase “C is connected between A and B” can mean that one end of C is connected to A and the other end of C is connected to B and that C is disposed in series with a path connecting A and B. The phrase “Path connecting A and B” can refer to a path constituted by a conductor which electrically connects A to B.

In the explanation of the arrangement of components, the phrase “a component is disposed in or on a substrate (or a module laminate)” includes the meaning that the component is disposed on a main surface of the substrate or the module laminate and the meaning that the component is disposed in the substrate or the module laminate. The phrase “A component is disposed on a main surface of a substrate (or a module laminate)” includes the meaning that the component is disposed on a main surface of the substrate or the module laminate while being in contact with the main surface, and also includes the meaning that the component is disposed over the main surface without contacting it (for example, the component is placed on another component which is in contact with the main surface). The phrase “A component is disposed on a main surface of a substrate (or a module laminate)” may include the meaning that the component is disposed in a depression formed on the main surface. In the explanation of the arrangement of components, the phrase “in a plan view of a module laminate” can mean that an object is orthographically projected on an xy plane from the positive side of the z axis and is viewed from this side.

The phrase “C is closer to A than B is” can mean that the distance between A and C is shorter than that between A and B. The phrase “Distance between A and B” can refer to the shortest distance between A and B. That is, “distance between A and B” refers to the length of the shortest line segment among multiple line segments connecting a certain point on the surface of A and a certain point on the surface of B.

In the following description, “a terminal” can refer to a point at which a conductor within an element terminates. When the impedance of a conductor between elements is sufficiently low, a terminal can be interpreted, not as a single point, but as certain points on the conductor between the elements or as the entire conductor.

For the purpose of this disclosure, terms representing the relationship between elements, such as “being parallel” and “being vertical”, terms representing the shape of an element, such as “being rectangular”, and ranges of numerical values are not necessarily to be interpreted in an exact sense, but to be interpreted in a broad sense. For instance, such terms and ranges cover substantially equivalent shapes and ranges, for example, about several percent of allowance is given.

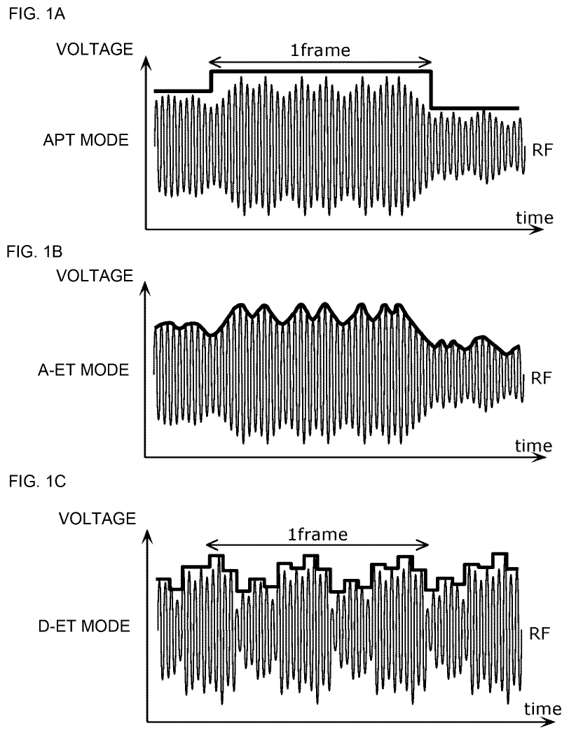

As a technology for amplifying a radio-frequency signal with high efficiency, the following tracking mode will first be explained in which a power supply voltage is dynamically adjusted over time based on a radio-frequency signal and is then supplied to a power amplifier. The tracking mode is a mode in which a power supply voltage to be applied to a power amplifier is dynamically adjusted. There are several types of tracking modes. In this example, the APT mode, A-ET mode, and D-ET mode will be explained below with reference to FIGS. 1A, 1B, and 1C, respectively. In FIGS. 1A through 1C, the horizontal axis indicates the time, and the vertical axis indicates the voltage. The thick solid line represents the power supply voltage, while the thin solid line (waveform) represents a modulated signal.

FIG. 1A is a graph illustrating an example of the transition of the power supply voltage in the APT mode. In the APT mode, based on average power, the power supply voltage is varied to multiple discrete voltage levels in units of frames.

A frame is a unit which forms a radio-frequency signal (modulated signal). For example, 5GNR (5th Generation New Radio) and LTE (Long Term Evolution) define that a frame includes ten subframes, each subframe includes multiple slots, and each slot is constituted by multiple symbols. The subframe length is 1 ms, and the frame length is 10 ms.

The mode in which the voltage level is varied in units of frames or in a larger unit based on average power is called the APT mode. The APT mode is distinguished from a mode in which the voltage level is varied in a unit (subframe, slot, or symbol, for example) smaller than a frame.

FIG. 1B is a graph illustrating an example of the transition of the power supply voltage in the A-ET mode. In the A-ET mode, the power supply voltage is continuously varied based on an envelope signal. In the A-ET mode, the power supply voltage can track the envelope of a modulated signal.

The envelope signal is a signal indicating the envelope of a modulated signal. The envelope value is represented by a square root of (I²+Q²), for example. (I, Q) is a constellation point. The constellation point is a point of a digital modulated signal on a constellation diagram. (I, Q) is determined by a BBIC (Baseband Integrated Circuit) based on transmission information, for example.

FIG. 1C is a graph illustrating an example of the transition of the power supply voltage in the D-ET mode. In the D-ET mode, based on an envelope signal, the power supply voltage is varied to multiple discrete voltage levels within one frame. In the D-ET mode, the power supply voltage can track the envelope of a modulated signal. In D-ET, the power supply voltage is varied at shorter time intervals than APT.

### EXEMPLARY EMBODIMENT

An exemplary embodiment will be described below.

### [1. Circuit Configuration of Communication Device 7]

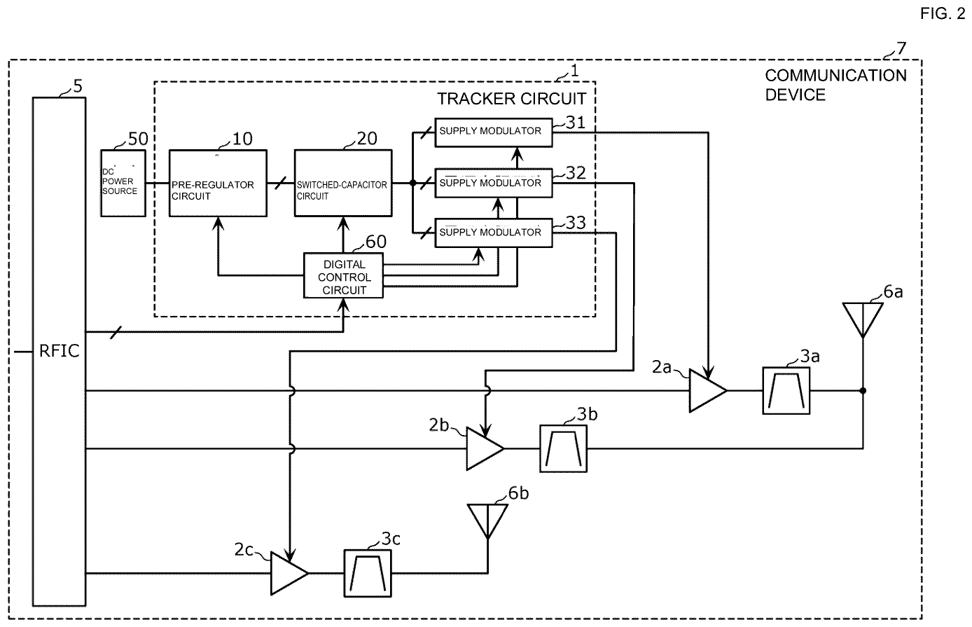

The circuit configuration of a communication device 7 according to the exemplary embodiment will first be discussed below with reference to FIG. 2. FIG. 2 is a circuit diagram of the communication device 7 according to the exemplary embodiment.

The circuit configuration shown in FIG. 2 is only an example. The communication device 7 can be implemented by using any of a variety of circuit implementations and circuit technologies. Hence, the following explanation of the communication device 7 is not to be interpreted in a limited manner.

The communication device 7 in the exemplary embodiment corresponds to UE in a cellular network (also called a mobile network) and is typically a mobile phone, a smartphone, a tablet computer, or a wearable device, for example. The communication device 7 may be an IoT (Internet of Things) sensor device, a medical/healthcare device, a vehicle, an UAV (Unmanned Aerial Vehicle) (known as a drone), or an AGV (Automated Guided Vehicle). The communication device 7 may serve as a BS (Base Station) in a cellular network.

As illustrated in FIG. 2, the communication device 7 includes a tracker circuit 1, power amplifiers 2a through 2c, filters 3a through 3c, a RFIC (Radio Frequency Integrated Circuit) 5, a primary antenna 6a, a secondary antenna 6b, and a direct current (DC) power source 50.

The tracker circuit 1 is able to supply multiple discrete voltages to the power amplifiers 2a through 2c in the D-ET mode. The tracker circuit 1 may also supply multiple discrete voltages to the power amplifiers 2a through 2c in the APT mode. As shown in FIG. 2, the tracker circuit 1 includes a pre-regulator circuit 10, a switched-capacitor circuit 20, supply modulators 31 through 33, and a digital control circuit 60.

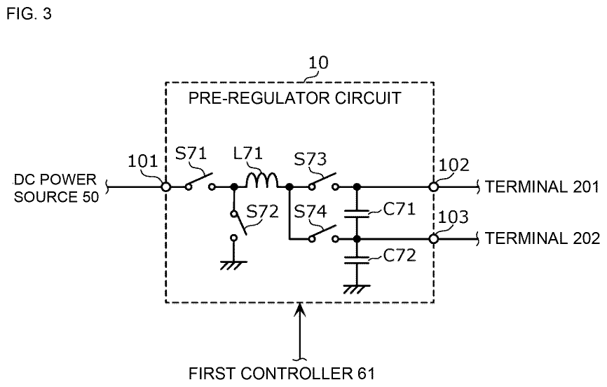

The pre-regulator circuit 10 may also be called a magnetic regulator or a DC (Direct Current)-to-DC converter. In the exemplary embodiment, the pre-regulator circuit 10 is a buck converter and is able to convert an output voltage supplied from the DC power source 50 into an input voltage (regulated voltage) to be input into the switched-capacitor circuit 20. The pre-regulator circuit 10 may be a buck-boost converter or a boost converter. The pre-regulator circuit 10 can vary the input voltage to be input into the switched-capacitor circuit 20 based on a control signal from the RFIC 5, for example. The pre-regulator circuit 10 may be omitted from the tracker circuit 1. The circuit configuration of the pre-regulator circuit 10 will be discussed later with reference to FIG. 3.

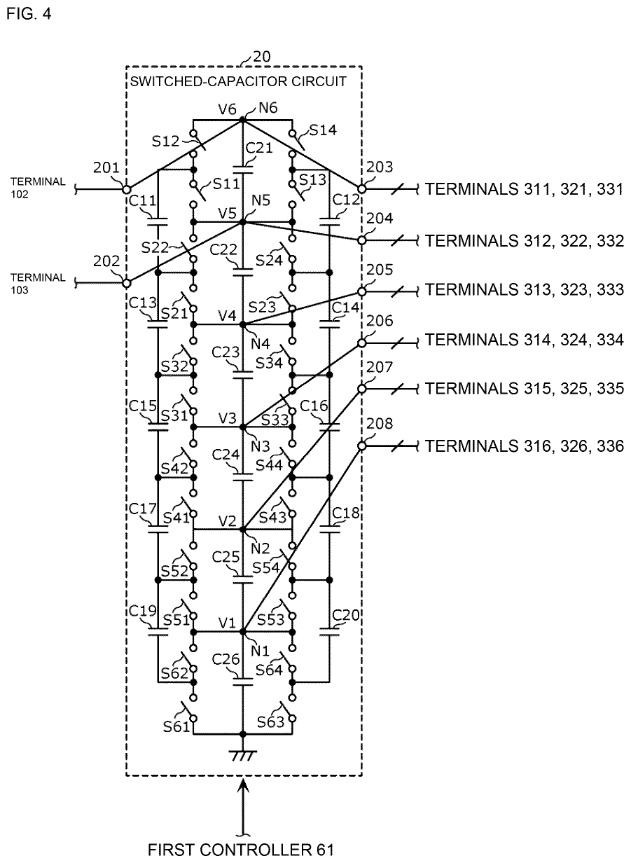

The switched-capacitor circuit 20 is able to generate multiple discrete voltages based on the regulated voltage supplied from the pre-regulator circuit 10. The circuit configuration of the switched-capacitor circuit 20 will be discussed later with reference to FIG. 4.

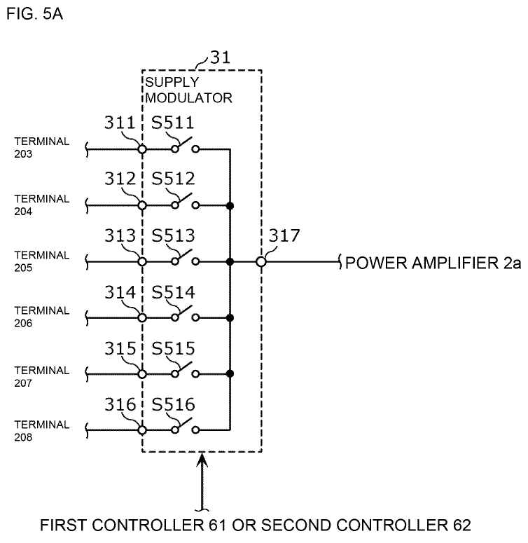

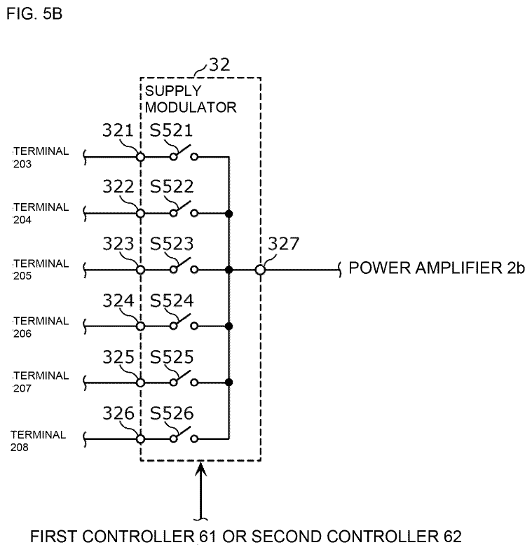

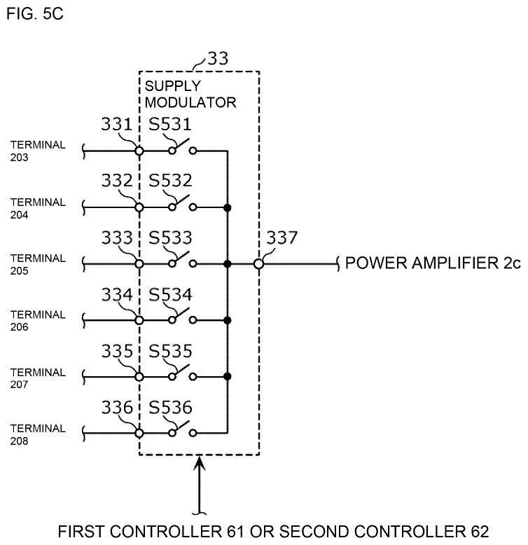

The supply modulator 31 is an example of a first supply modulator. The supply modulator 32 is an example of a second supply modulator. The supply modulator 33 is an example of a third supply modulator. The supply modulators 31 through 33 are able to selectively output at least one of the multiple discrete voltages generated in the switched-capacitor circuit 20 to the power amplifiers 2a through 2c, respectively. The supply modulators 31 through 33 can each select at least one of the multiple discrete voltages, independently from each other. The circuit configurations of the supply modulators 31 through 33 will be discussed later with reference to FIGS. 5A through 5C, respectively.

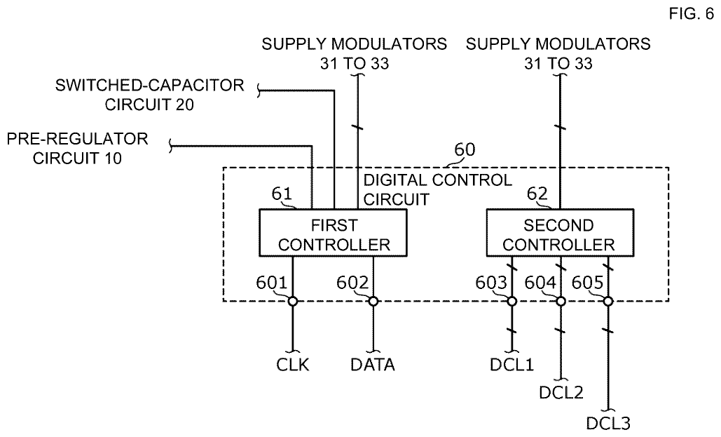

The digital control circuit 60 is able to control the pre-regulator circuit 10, the switched-capacitor circuit 20, and the supply modulators 31 through 33, based on digital control signals supplied from the RFIC 5. More specifically, the digital control circuit 60 can control switches included in the pre-regulator circuit 10, switches included in the switched-capacitor circuit 20, and switches included in the supply modulators 31 through 33. The digital control circuit 60 may be omitted from the tracker circuit 1. The circuit configuration of the digital control circuit 60 will be discussed later with reference to FIG. 6.

The DC power source 50 is able to supply a DC voltage to the pre-regulator circuit 10. As the DC power source 50, a rechargeable battery, for example, can be used. However, the DC power source 50 is not limited to a rechargeable battery.

The power amplifier 2a is an example of a first power amplifier and is connected between the RFIC 5 and the filter 3a. The power amplifier 2b is an example of a second power amplifier and is connected between the RFIC 5 and the filter 3b. The power amplifier 2c is an example of a third power amplifier and is connected between the RFIC 5 and the filter 3c. The power amplifiers 2a through 2c are also connected to the tracker circuit 1. Each of the power amplifiers 2a through 2c is able to amplify a radio-frequency signal supplied from the RFIC 5 by using multiple discrete voltages supplied from the tracker circuit 1.

The filter 3a is a band pass filter having a passband including band A and is connected between the power amplifier 2a and the primary antenna 6a. The filter 3b is a band pass filter having a passband including band B and is connected between the power amplifier 2b and the primary antenna 6a. The filter 3c is a band pass filter having a passband including band C and is connected between the power amplifier 2c and the secondary antenna 6b. The filters 3a through 3c may be omitted from the communication device 7.

Band A through band C are frequency bands used for a communication system constructed using a radio access technology (RAT), and are predefined by a standardizing body (such as 3GPP (registered trademark) and IEEE (Institute of Electrical and Electronics Engineers). Examples of the communication system are a 5GNR system, an LTE system, and a WLAN (Wireless Local Area Network) system.

As a combination of band A through band C supporting 3Tx, the combinations indicated in the following Table 1 may be used. However, the combinations of band A through band C are not limited to those in Table 1.

TABLE 1

| Band combination | Band A | Band B | Band C |
|---|---|---|---|
| CA_n28A-n41A | n28 | n41 | n41 |
| CA_n28A-n78A | n28 | n78 | n78 |
| CA_n8A-n78A | n8 | n78 | n78 |
| CA_n41A-n71A | n71 | n41 | n41 |
| CA_n41A-n77A | n41 | n77 | n77 |
| | n77 | n41 | n41 |
| CA_n26A-n78A | n26 | n78 | n78 |
| DC_3A_n78A | 3 | n78 | n78 |
| DC_40A_n78A | 40 | n78 | n78 |

The primary antenna 6a is connected to the filters 3a and 3b and transmits radio-frequency signals having passed through the filters 3a and 3b. The secondary antenna 6b is connected to the filter 3c and transmits a radio-frequency signal having passed through the filter 3c. The primary antenna and the secondary antenna are antennas installed at different positions. The primary antenna 6a and the secondary antenna 6b may be omitted from the communication device 7.

The circuit configuration of the communication device 7 shown in FIG. 2 is only an example and is not intended to limit the configuration of the communication device 7. For example, the communication device 7 may include a baseband signal processing circuit that executes signal processing by using a frequency band lower than a radio-frequency signal.

### [2. Circuit Configuration of Pre-Regulator Circuit 10]

The configuration of the pre-regulator circuit 10 will be discussed below with reference to FIG. 3. FIG. 3 is a circuit diagram of the pre-regulator circuit 10 according to the exemplary embodiment.

The circuit configuration shown in FIG. 3 is only an example. The pre-regulator circuit 10 can be implemented by using any of a variety of circuit implementations and circuit technologies. Hence, the following explanation of the pre-regulator circuit 10 is not to be interpreted in a limited manner.

The pre-regulator circuit 10 includes an input terminal 101, output terminals 102 and 103, switches S71 through S74, a power inductor L71, and capacitors C71 and C72.

The input terminal 101 is a terminal for receiving a DC voltage from the DC power source 50. The input terminal 101 is connected to the DC power source 50 at the outside of the pre-regulator circuit 10 and is connected to the switch S71 at the inside of the pre-regulator circuit 10.

The output terminals 102 and 103 are terminals for supplying a regulated voltage to the switched-capacitor circuit 20. The output terminal 102 is connected to an input terminal 201 of the switched-capacitor circuit 20 at the outside of the pre-regulator circuit 10 and is connected to the switch S73 at the inside of the pre-regulator circuit 10. The output terminal 103 is connected to an input terminal 202 of the switched-capacitor circuit 20 at the outside of the pre-regulator circuit 10 and is connected to the switch S74 at the inside of the pre-regulator circuit 10. One of the output terminals 102 and 103 may be omitted.

The power inductor L71 is an inductor for stepping up and stepping down the DC voltage. One end of the power inductor L71 is connected to the switches S71 and S72, and the other end of the power inductor L71 is connected to the switches S73 and S74.

The switch S71 is an example of a fifteenth switch and is connected between the input terminal 101 and one end of the power inductor L71. With this connection configuration, as a result of changing the opening/closing of the switch S71, the switch S71 can selectively connect the input terminal 101 to one end of the power inductor L71 or disconnect the input terminal 101 from this end of the power inductor L71.

The switch S72 is an example of a sixteenth switch and is connected between one end of the power inductor L71 and a ground. With this connection configuration, as a result of changing the opening/closing of the switch S72, the switch S72 can selectively connect one end of the power inductor L71 to a ground or disconnect this end of the power inductor L71 from a ground.

The switch S73 is an example of a seventeenth switch and is connected between the other end of the power inductor L71 and the output terminal 102. With this connection configuration, as a result of changing the opening/closing of the switch S73, the switch S73 can selectively connect the other end of the power inductor L71 to the output terminal 102 or disconnect the other end of the power inductor L71 from the output terminal 102.

The switch S74 is an example of an eighteenth switch and is connected between the other end of the power inductor L71 and the output terminal 103. With this connection configuration, as a result of changing the opening/closing of the switch S74, the switch S74 can selectively connect the other end of the power inductor L71 to the output terminal 103 or disconnect the other end of the power inductor L71 from the output terminal 103.

The capacitor C71 is connected between the capacitor C72 and a path between the switch S73 and the output terminal 102. More specifically, one of the two electrodes of the capacitor C71 is connected to the switch S73 and the output terminal 102, while the other one of the two electrodes of the capacitor C71 is connected to the switch S74, the output terminal 103, and the capacitor C72.

The capacitor C72 is connected between a ground and a path between the switch S74 and the output terminal 103. More specifically, one of the two electrodes of the capacitor C72 is connected to the switch S74, the output terminal 103, and the capacitor C71, while the other one of the two electrodes of the capacitor C72 is connected to a ground.

The switches S73 and S74 are controlled to be ON mutually exclusively. That is, it is not possible that both of the switches S73 and S74 are closed at the same time. As a result of closing the switches S73 and S74 mutually exclusively, the pre-regulator circuit 10 can selectively supply the regulated voltage to one of the input terminals 201 and 202 of the switched-capacitor circuit 20.

The configuration of the pre-regulator circuit 10 shown in FIG. 3 is only an example and is not intended to limit the configuration of the pre-regulator circuit 10. For example, one of the switches S71 and S72 may be replaced by a diode. All of or part of the pre-regulator circuit 10 may be omitted from the tracker circuit 1.

### [3. Circuit Configuration of Switched-Capacitor Circuit 20]

The circuit configuration of the switched-capacitor circuit 20 will now be discussed below with reference to FIG. 4. FIG. 4 is a circuit diagram of the switched-capacitor circuit 20 according to the exemplary embodiment.

The circuit configuration shown in FIG. 4 is only an example. The switched-capacitor circuit 20 can be implemented by using any of a variety of circuit implementations and circuit technologies. Hence, the following explanation of the switched-capacitor circuit 20 is not to be interpreted in a limited manner.

The switched-capacitor circuit 20 has a ladder circuit configuration. More specifically, the switched-capacitor circuit 20 includes capacitors C11 through C26, switches S11 through S14, S21 through S24, S31 through S34, S41 through S44, S51 through S54, and S61 through S64, input terminals 201 and 202, and output terminals 203 through 208. Energy and electric charge are input from the pre-regulator circuit 10 into a node N6 (an example of a first node) via the input terminal 201 or a node N5 (an example of a second node) via the input terminal 202 and are output from the nodes N6 through N1 to the supply modulators 31 through 33 via the output terminals 203 through 208, respectively.

The input terminal 201 is a terminal for receiving the regulated voltage from the pre-regulator circuit 10. The input terminal 201 is connected to the output terminal 102 of the pre-regulator circuit 10 at the outside of the switched-capacitor circuit 20 and is connected to the node N6 at the inside of the switched-capacitor circuit 20.

The input terminal 202 is a terminal for receiving the regulated voltage from the pre-regulator circuit 10. The input terminal 202 is connected to the output terminal 103 of the pre-regulator circuit 10 at the outside of the switched-capacitor circuit 20 and is connected to the node N5 at the inside of the switched-capacitor circuit 20.

The output terminal 203 is a terminal for supplying the discrete voltage (V6) to the supply modulators 31 through 33. The output terminal 203 is connected to an input terminal 311 of the supply modulator 31, an input terminal 321 of the supply modulator 32, and an input terminal 331 of the supply modulator 33 at the outside of the switched-capacitor circuit 20. The output terminal 203 is connected to the node N6 at the inside of the switched-capacitor circuit 20. The output terminal 203 may be integrated with the input terminal 201.

The output terminal 204 is a terminal for supplying the discrete voltage (V5) to the supply modulators 31 through 33. The output terminal 204 is connected to an input terminal 312 of the supply modulator 31, an input terminal 322 of the supply modulator 32, and an input terminal 332 of the supply modulator 33 at the outside of the switched-capacitor circuit 20. The output terminal 204 is connected to the node N5 at the inside of the switched-capacitor circuit 20. The output terminal 204 may be integrated with the input terminal 202.

The output terminal 205 is a terminal for supplying the discrete voltage (V4) to the supply modulators 31 through 33. The output terminal 205 is connected to an input terminal 313 of the supply modulator 31, an input terminal 323 of the supply modulator 32, and an input terminal 333 of the supply modulator 33 at the outside of the switched-capacitor circuit 20. The output terminal 205 is connected to the node N4 at the inside of the switched-capacitor circuit 20.

The output terminal 206 is a terminal for supplying the discrete voltage (V3) to the supply modulators 31 through 33. The output terminal 206 is connected to an input terminal 314 of the supply modulator 31, an input terminal 324 of the supply modulator 32, and an input terminal 334 of the supply modulator 33 at the outside of the switched-capacitor circuit 20. The output terminal 206 is connected to the node N3 at the inside of the switched-capacitor circuit 20.

The output terminal 207 is a terminal for supplying the discrete voltage (V2) to the supply modulators 31 through 33. The output terminal 207 is connected to an input terminal 315 of the supply modulator 31, an input terminal 325 of the supply modulator 32, and an input terminal 335 of the supply modulator 33 at the outside of the switched-capacitor circuit 20. The output terminal 207 is connected to the node N2 at the inside of the switched-capacitor circuit 20.

The output terminal 208 is a terminal for supplying the discrete voltage (V1) to the supply modulators 31 through 33. The output terminal 208 is connected to an input terminal 316 of the supply modulator 31, an input terminal 326 of the supply modulator 32, and an input terminal 336 of the supply modulator 33 at the outside of the switched-capacitor circuit 20. The output terminal 208 is connected to the node N1 at the inside of the switched-capacitor circuit 20.

The capacitors C11 through C20 each serve as a flying capacitor (may also be called a transfer capacitor) and is used for stepping up and/or stepping down the regulated voltage supplied from the pre-regulator circuit 10. More specifically, the capacitors C11 through C20 transfer electric charge between the capacitors C11 through C20, the nodes N1 through N6, and a ground so that voltages V1 through V6 which satisfy the relationship of (V6−V5):(V5−V4):(V4−V3):(V3−V2):(V2−V1):(V1−G)=1:1:1:1:1:1 and V6>V5>V4>V3>V2>V1>VG can be maintained at the nodes N1 through N6, respectively. VG represents a ground potential.

The capacitor C11 is an example of a first capacitor and has two electrodes, which are an example of first and second electrodes. One (first electrode) of the two electrodes of the capacitor C11 is connected to one end of the switch S11 and one end of the switch S12. The other one (second electrode) of the two electrodes of the capacitor C11 is connected to one end of the switch S21 and one end of the switch S22.

The capacitor C12 is an example of a second capacitor and has two electrodes, which are an example of third and fourth electrodes. One (third electrode) of the two electrodes of the capacitor C12 is connected to one end of the switch S13 and one end of the switch S14. The other one (fourth electrode) of the two electrodes of the capacitor C12 is connected to one end of the switch S23 and one end of the switch S24.

One of the two electrodes of the capacitor C13 is connected to one end of the switch S21 and one end of the switch S22. The other one of the two electrodes of the capacitor C13 is connected to one end of the switch S31 and one end of the switch S32.

One of the two electrodes of the capacitor C14 is connected to one end of the switch S23 and one end of the switch S24. The other one of the two electrodes of the capacitor C14 is connected to one end of the switch S33 and one end of the switch S34.

One of the two electrodes of the capacitor C15 is connected to one end of the switch S31 and one end of the switch S32. The other one of the two electrodes of the capacitor C15 is connected to one end of the switch S41 and one end of the switch S42.

One of the two electrodes of the capacitor C16 is connected to one end of the switch S33 and one end of the switch S34. The other one of the two electrodes of the capacitor C16 is connected to one end of the switch S43 and one end of the switch S44.

One of the two electrodes of the capacitor C17 is connected to one end of the switch S41 and one end of the switch S42. The other one of the two electrodes of the capacitor C17 is connected to one end of the switch S51 and one end of the switch S52.

One of the two electrodes of the capacitor C18 is connected to one end of the switch S43 and one end of the switch S44. The other one of the two electrodes of the capacitor C18 is connected to one end of the switch S53 and one end of the switch S54.

One of the two electrodes of the capacitor C19 is connected to one end of the switch S51 and one end of the switch S52. The other one of the two electrodes of the capacitor C19 is connected to one end of the switch S61 and one end of the switch S62.

One of the two electrodes of the capacitor C20 is connected to one end of the switch S53 and one end of the switch S54. The other one of the two electrodes of the capacitor C20 is connected to one end of the switch S63 and one end of the switch S64.

As a result of repeating a first phase and a second phase, the capacitors C11 and C12 can complementarily perform charging and discharging. Likewise, as a result of repeating the first phase and the second phase, the capacitors C13 and C14 can complementarily perform charging and discharging. As a result of repeating the first phase and the second phase, the capacitors C15 and C16 can complementarily perform charging and discharging. As a result of repeating the first phase and the second phase, the capacitors C17 and C18 can complementarily perform charging and discharging.

More specifically, in the first phase, the switches S12, S13, S22, S23, S32, S33, S42, S43, S52, S53, S62, and S63 are closed, while the switches S11, S14, S21, S24, S31, S34, S41, S44, S51, S54, S61, and S64 are opened. As a result, one of the two electrodes of the capacitor C11 is connected to the node N6. The other one of the two electrodes of the capacitor C11, one of the two electrodes of the capacitor C12, and one of the two electrodes of the capacitor C13 are connected to the node N5. The other one of the two electrodes of the capacitor C12, the other one of the two electrodes of the capacitor C13, one of the two electrodes of the capacitor C14, and one of the two electrodes of the capacitor C15 are connected to the node N4. The other one of the two electrodes of the capacitor C14, the other one of the two electrodes of the capacitor C15, one of the two electrodes of the capacitor C16, and one of the two electrodes of the capacitor C17 are connected to the node N3. The other one of the two electrodes of the capacitor C16, the other one of the two electrodes of the capacitor C17, one of the two electrodes of the capacitor C18, and one of the two electrodes of the capacitor C19 are connected to the node N2. The other one of the two electrodes of the capacitor C18, the other one of the two electrodes of the capacitor C19, and one of the two electrodes of the capacitor C20 are connected to the node N1. The other one of the two electrodes of the capacitor C20 is connected to a ground.

In the second phase, the switches S11, S14, S21, S24, S31, S34, S41, S44, S51, S54, S61, and S64 are closed, while the switches S12, S13, S22, S23, S32, S33, S42, S43, S52, S53, S62, and S63 are opened. As a result, one of the two electrodes of the capacitor C12 is connected to the node N6. One of the two electrodes of the capacitor C11, the other one of the two electrodes of the capacitor C12, and one of the two electrodes of the capacitor C14 are connected to the node N5. The other one of the two electrodes of the capacitor C11, one of the two electrodes of the capacitor C13, the other one of the two electrodes of the capacitor C14, and one of the two electrodes of the capacitor C16 are connected to the node N4. The other one of the two electrodes of the capacitor C13, one of the two electrodes of the capacitor C15, the other one of the two electrodes of the capacitor C16, and one of the two electrodes of the capacitor C18 are connected to the node N3. The other one of the two electrodes of the capacitor C15, one of the two electrodes of the capacitor C17, the other one of the two electrodes of the capacitor C18, and one of the two electrodes of the capacitor C20 are connected to the node N2. The other one of the two electrodes of the capacitor C17, one of the two electrodes of the capacitor C19, and the other one of the two electrodes of the capacitor C20 are connected to the node N1. The other one of the two electrodes of the capacitor C19 is connected to a ground.

As a result of repeating the first phase and the second phase, when, for example, one of the capacitors C11 and C12 is being charged from the node N6, the other one of the capacitors C11 and C12 can discharge to the capacitor C22. That is, the capacitors C11 and C12 can complementarily perform charging and discharging.

The capacitors C21 through C26 are smoothing capacitors and are used for holding and smoothing the output voltages at the nodes N6 through N1, respectively.

The capacitor C21 is connected between the nodes N6 and N5. More specifically, one of the two electrodes of the capacitor C21 is connected to the node N6, while the other one of the two electrodes of the capacitor C21 is connected to the node N5.

The capacitor C22 is connected between the nodes N5 and N4. More specifically, one of the two electrodes of the capacitor C22 is connected to the node N5, while the other one of the two electrodes of the capacitor C22 is connected to the node N4.

The capacitor C23 is connected between the nodes N4 and N3. More specifically, one of the two electrodes of the capacitor C23 is connected to the node N4, while the other one of the two electrodes of the capacitor C23 is connected to the node N3.

The capacitor C24 is connected between the nodes N3 and N2. More specifically, one of the two electrodes of the capacitor C24 is connected to the node N3, while the other one of the two electrodes of the capacitor C24 is connected to the node N2.

The capacitor C25 is connected between the nodes N2 and N1. More specifically, one of the two electrodes of the capacitor C25 is connected to the node N2, while the other one of the two electrodes of the capacitor C25 is connected to the node N1.

The capacitor C26 is connected between the node N1 and a ground. More specifically, one of the two electrodes of the capacitor C26 is connected to the node N1, while the other one of the two electrodes of the capacitor C26 is connected to the ground.

The switch S11 is an example of a first switch and is connected between the capacitor C11 and the node N5. More specifically, one end of the switch S11 is connected to one of the two electrodes of the capacitor C11, while the other end of the switch S11 is connected to the node N5.

The switch S12 is an example of a second switch and is connected between the capacitor C11 and the node N6. More specifically, one end of the switch S12 is connected to one of the two electrodes of the capacitor C11, while the other end of the switch S12 is connected to the node N6.

The switch S13 is an example of a third switch and is connected between the capacitor C12 and the node N5. More specifically, one end of the switch S13 is connected to one of the two electrodes of the capacitor C12, while the other end of the switch S13 is connected to the node N5. That is, the other end of the switch S13 is connected to the other end of the switch S11 and the other end of the switch S22.

The switch S14 is an example of a fourth switch and is connected between the capacitor C12 and the node N6. More specifically, one end of the switch S14 is connected to one of the two electrodes of the capacitor C12, while the other end of the switch S14 is connected to the node N6. That is, the other end of the switch S14 is connected to the other end of the switch S12 via the node N6.

The switch S21 is an example of a fifth switch and is connected between the node N4 and a node between the capacitors C11 and C13. More specifically, one end of the switch S21 is connected to the other one of the two electrodes of the capacitor C11 and one of the two electrodes of the capacitor C13, while the other end of the switch S21 is connected to the node N4.

The switch S22 is an example of a sixth switch and is connected between the node N5 and a node between the capacitors C11 and C13. More specifically, one end of the switch S22 is connected to the other one of the two electrodes of the capacitor C11 and one of the two electrodes of the capacitor C13, while the other end of the switch S22 is connected to the node N5.

The switch S23 is an example of a seventh switch and is connected between the node N4 and a node between the capacitors C12 and C14. More specifically, one end of the switch S23 is connected to the other one of the two electrodes of the capacitor C12 and one of the two electrodes of the capacitor C14, while the other end of the switch S23 is connected to the node N4.

The switch S24 is an example of an eighth switch and is connected between the node N5 and a node between the capacitors C12 and C14. More specifically, one end of the switch S24 is connected to the other one of the two electrodes of the capacitor C12 and one of the two electrodes of the capacitor C14, while the other end of the switch S24 is connected to the node N5. That is, the other end of the switch S24 is connected to the other end of the switch S11, the other end of the switch S22, and the other end of the switch S13 via the node N5.

The switch S31 is connected between the node N3 and a node between the capacitors C13 and C15. More specifically, one end of the switch S31 is connected to the other one of the two electrodes of the capacitor C13 and one of the two electrodes of the capacitor C15, while the other end of the switch S31 is connected to the node N3.

The switch S32 is connected between the node N4 and a node between the capacitors C13 and C15. More specifically, one end of the switch S32 is connected to the other one of the two electrodes of the capacitor C13 and one of the two electrodes of the capacitor C15, while the other end of the switch S32 is connected to the node N4.

The switch S33 is connected between the node N3 and a node between the capacitors C14 and C16. More specifically, one end of the switch S33 is connected to the other one of the two electrodes of the capacitor C14 and one of the two electrodes of the capacitor C16, while the other end of the switch S33 is connected to the node N3.

The switch S34 is connected between the node N4 and a node between the capacitors C14 and C16. More specifically, one end of the switch S34 is connected to the other one of the two electrodes of the capacitor C14 and one of the two electrodes of the capacitor C16, while the other end of the switch S34 is connected to the node N4.

The switch S41 is connected between the node N2 and a node between the capacitors C15 and C17. More specifically, one end of the switch S41 is connected to the other one of the two electrodes of the capacitor C15 and one of the two electrodes of the capacitor C17, while the other end of the switch S41 is connected to the node N2.

The switch S42 is connected between the node N3 and a node between the capacitors C15 and C17. More specifically, one end of the switch S42 is connected to the other one of the two electrodes of the capacitor C15 and one of the two electrodes of the capacitor C17, while the other end of the switch S42 is connected to the node N3.

The switch S43 is connected between the node N2 and a node between the capacitors C16 and C18. More specifically, one end of the switch S43 is connected to the other one of the two electrodes of the capacitor C16 and one of the two electrodes of the capacitor C18, while the other end of the switch S43 is connected to the node N2.

The switch S44 is connected between the node N3 and a node between the capacitors C16 and C18. More specifically, one end of the switch S44 is connected to the other one of the two electrodes of the capacitor C16 and one of the two electrodes of the capacitor C18, while the other end of the switch S44 is connected to the node N3.

The switch S51 is connected between the node N1 and a node between the capacitors C17 and C19. More specifically, one end of the switch S51 is connected to the other one of the two electrodes of the capacitor C17 and one of the two electrodes of the capacitor C19, while the other end of the switch S51 is connected to the node N1.

The switch S52 is connected between the node N2 and a node between the capacitors C17 and C19. More specifically, one end of the switch S52 is connected to the other one of the two electrodes of the capacitor C17 and one of the two electrodes of the capacitor C19, while the other end of the switch S52 is connected to the node N2.

The switch S53 is connected between the node N1 and a node between the capacitors C18 and C20. More specifically, one end of the switch S53 is connected to the other one of the two electrodes of the capacitor C18 and one of the two electrodes of the capacitor C20, while the other end of the switch S53 is connected to the node N1.

The switch S54 is connected between the node N2 and a node between the capacitors C18 and C20. More specifically, one end of the switch S54 is connected to the other one of the two electrodes of the capacitor C18 and one of the two electrodes of the capacitor C20, while the other end of the switch S54 is connected to the node N2.

The switch S61 is connected between the capacitor C19 and a ground. More specifically, one end of the switch S61 is connected to the other one of the two electrodes of the capacitor C19, while the other end of the switch S61 is connected to the ground.

The switch S62 is connected between the capacitor C19 and the node N1. More specifically, one end of the switch S62 is connected to the other one of the two electrodes of the capacitor C19, while the other end of the switch S62 is connected to the node N1.

The switch S63 is connected between the capacitor C20 and a ground. More specifically, one end of the switch S63 is connected to the other one of the two electrodes of the capacitor C20, while the other end of the switch S63 is connected to the ground.

The switch S64 is connected between the capacitor C20 and the node N1. More specifically, one end of the switch S64 is connected to the other one of the two electrodes of the capacitor C20, while the other end of the switch S64 is connected to the node N1.

Based on a control signal from the digital control circuit 60, the opening/closing of a first set of switches including the switches S12, S13, S22, S23, S32, S33, S42, S43, S52, S53, S62, and S63 and that of a second set of switches including the switches S11, S14, S21, S24, S31, S34, S41, S44, S51, S54, S61, and S64 are switched therebetween in a complementary manner. More specifically, in the first phase, the switches included in the first set are closed, while the switches included in the second set are opened. Conversely, in the second phase, the switches included in the first set are opened, while the switches included in the second set are closed.

For example, in one of the first and second phases, the capacitor C11 charges the capacitors C21 and C22, and in the other one of the first and second phases, the capacitor C12 charges the capacitors C21 and C22. That is, the capacitors C21 and C22 are constantly charged from the capacitor C11 or C12. Hence, even if a current flows from the nodes N6 and N5 to the supply modulators 31 through 33 at high speed, the nodes N6 and N5 are recharged quickly, thereby reducing potential variations at the nodes N6 and N5.

The switched-capacitor circuit 20 is operated in this manner so as to maintain a substantially equal voltage across each of the capacitors C21 through C26. More specifically, at the nodes N1 through N6 labeled with V1 through V6, respectively, the voltages V1 through V6 which satisfy the relationship of (V6−V5):(V5−V4):(V4−V3):(V3−V2):(V2-V1):(V1−G)=1:1:1:1:1:1 can be maintained.

The voltage ratio (V6−V5):(V5−V4):(V4−V3):(V3−V2):(V2−V1):(V1−G) is not limited to 1:1:1:1:1:1 and may be designed to a desired ratio.

### [4. Circuit Configurations of Supply Modulators 31 Through 33]

The circuit configurations of the supply modulators 31 through 33 will be described below with reference to FIGS. 5A through 5C, respectively. FIGS. 5A through 5C are circuit diagrams of the supply modulators 31 through 33 according to the exemplary embodiment.

The circuit configurations shown in FIGS. 5A through 5C are only examples. The supply modulators 31 through 33 can be implemented by using any of a variety of circuit implementations and circuit technologies. Hence, the following explanation of the supply modulators 31 through 33 is not to be interpreted in a limited manner.

### [4.1 Circuit Configuration of Supply Modulator 31]

The circuit configuration of the supply modulator 31 will first be explained below with reference to FIG. 5A. The supply modulator 31 includes input terminals 311 through 316, switches S511 through S516, and an output terminal 317.

The input terminals 311 through 316 are terminals for receiving multiple discrete voltages (V6 through V1) generated in the switched-capacitor circuit 20. The input terminals 311 through 316 are respectively connected to the output terminals 203 through 208 of the switched-capacitor circuit 20 at the outside of the supply modulator 31 and are respectively connected to the switches S511 through S516 at the inside of the supply modulator 31.

The output terminal 317 is an example of a first output terminal and is a terminal for selectively supplying at least one of the discrete voltages to the power amplifier 2a. The output terminal 317 is connected to the power amplifier 2a at the outside of the supply modulator 31 and is connected to the switches S511 through S516 at the inside of the supply modulator 31.

The switch S511 is an example of a ninth switch and is connected between the input terminal 311 and the output terminal 317. With this connection configuration, as a result of the opening/closing of the switch S511 being changed by a control signal from the digital control circuit 60, the switch S511 can selectively connect the input terminal 311 to the output terminal 317 or disconnect the input terminal 311 from the output terminal 317.

The switch S512 is an example of a tenth switch and is connected between the input terminal 312 and the output terminal 317. With this connection configuration, as a result of the opening/closing of the switch S512 being changed by a control signal from the digital control circuit 60, the switch S512 can selectively connect the input terminal 312 to the output terminal 317 or disconnect the input terminal 312 from the output terminal 317.

The switch S513 is connected between the input terminal 313 and the output terminal 317. With this connection configuration, as a result of the opening/closing of the switch S513 being changed by a control signal from the digital control circuit 60, the switch S513 can selectively connect the input terminal 313 to the output terminal 317 or disconnect the input terminal 313 from the output terminal 317.

The switch S514 is connected between the input terminal 314 and the output terminal 317. With this connection configuration, as a result of the opening/closing of the switch S514 being changed by a control signal from the digital control circuit 60, the switch S514 can selectively connect the input terminal 314 to the output terminal 317 or disconnect the input terminal 314 from the output terminal 317.

The switch S515 is connected between the input terminal 315 and the output terminal 317. With this connection configuration, as a result of the opening/closing of the switch S515 being changed by a control signal from the digital control circuit 60, the switch S515 can selectively connect the input terminal 315 to the output terminal 317 or disconnect the input terminal 315 from the output terminal 317.

The switch S516 is connected between the input terminal 316 and the output terminal 317. With this connection configuration, as a result of the opening/closing of the switch S516 being changed by a control signal from the digital control circuit 60, the switch S516 can selectively connect the input terminal 316 to the output terminal 317 or disconnect the input terminal 316 from the output terminal 317.

In the exemplary embodiment, the switches S511 through S516 are controlled to be ON mutually exclusively. That is, the switches S511 through S516 are controlled such that only one of them is closed and the remaining switches are all opened. With this configuration, the supply modulator 31 can selectively connect one of the output terminals 203 through 208 of the switched-capacitor circuit 20 to the power amplifier 2a and supply the selected one of the discrete voltages (V1 through V6) to the power amplifier 2a.

The configuration of the supply modulator 31 shown in FIG. 5A is only an example and is not intended to limit the configuration of the supply modulator 31. Among others, the switches S511 through S516 may be configured and controlled in any manner when they can selectively connect at least one of the six input terminals 311 through 316 to the output terminal 317. For example, two of the switches S511 through S516 may be closed, and the remaining four of the switches S511 through S516 may be opened.

### [4.2 Circuit Configuration of Supply Modulator 32]

The circuit configuration of the supply modulator 32 will now be explained below with reference to FIG. 5B. The supply modulator 32 includes input terminals 321 through 326, switches S521 through S526, and an output terminal 327.

The input terminals 321 through 326 are terminals for receiving multiple discrete voltages (V6 through V1) generated in the switched-capacitor circuit 20. The input terminals 321 through 326 are respectively connected to the output terminals 203 through 208 of the switched-capacitor circuit 20 at the outside of the supply modulator 32 and are respectively connected to the switches S521 through S526 at the inside of the supply modulator 32.

The output terminal 327 is an example of a second output terminal and is a terminal for selectively supplying at least one of the discrete voltages to the power amplifier 2b. The output terminal 327 is connected to the power amplifier 2b at the outside of the supply modulator 32 and is connected to the switches S521 through S526 at the inside of the supply modulator 32.

The switch S521 is an example of an eleventh switch and is connected between the input terminal 321 and the output terminal 327. With this connection configuration, as a result of the opening/closing of the switch S521 being changed by a control signal from the digital control circuit 60, the switch S521 can selectively connect the input terminal 321 to the output terminal 327 or disconnect the input terminal 321 from the output terminal 327.

The switch S522 is an example of a twelfth switch and is connected between the input terminal 322 and the output terminal 327. With this connection configuration, as a result of the opening/closing of the switch S522 being changed by a control signal from the digital control circuit 60, the switch S522 can selectively connect the input terminal 322 to the output terminal 327 or disconnect the input terminal 322 from the output terminal 327.

The switch S523 is connected between the input terminal 323 and the output terminal 327. With this connection configuration, as a result of the opening/closing of the switch S523 being changed by a control signal from the digital control circuit 60, the switch S523 can selectively connect the input terminal 323 to the output terminal 327 or disconnect the input terminal 323 from the output terminal 327.

The switch S524 is connected between the input terminal 324 and the output terminal 327. With this connection configuration, as a result of the opening/closing of the switch S524 being changed by a control signal from the digital control circuit 60, the switch S524 can selectively connect the input terminal 324 to the output terminal 327 or disconnect the input terminal 324 from the output terminal 327.

The switch S525 is connected between the input terminal 325 and the output terminal 327. With this connection configuration, as a result of the opening/closing of the switch S525 being changed by a control signal from the digital control circuit 60, the switch S525 can selectively connect the input terminal 325 to the output terminal 327 or disconnect the input terminal 325 from the output terminal 327.

The switch S526 is connected between the input terminal 326 and the output terminal 327. With this connection configuration, as a result of the opening/closing of the switch S526 being changed by a control signal from the digital control circuit 60, the switch S526 can selectively connect the input terminal 326 to the output terminal 327 or disconnect the input terminal 326 from the output terminal 327.

In the exemplary embodiment, the switches S521 through S526 are controlled to be ON mutually exclusively. That is, the switches S521 through S526 are controlled such that only one of them is closed and the remaining switches are all opened. With this configuration, the supply modulator 32 can selectively connect one of the output terminals 203 through 208 of the switched-capacitor circuit 20 to the power amplifier 2b and supply the selected one of the discrete voltages (V1 through V6) to the power amplifier 2b.

The configuration of the supply modulator 32 shown in FIG. 5B is only an example and is not intended to limit the configuration of the supply modulator 32. Among others, the switches S521 through S526 may be configured and controlled in any manner when they can selectively connect at least one of the six input terminals 321 through 326 to the output terminal 327. For example, two of the switches S521 through S526 may be closed, and the remaining four of the switches S521 through S526 may be opened.

### [4.3 Circuit Configuration of Supply Modulator 33]

The circuit configuration of the supply modulator 33 will now be explained below with reference to FIG. 5C. The supply modulator 33 includes input terminals 331 through 336, switches S531 through S536, and an output terminal 337.

The input terminals 331 through 336 are terminals for receiving multiple discrete voltages (V6 through V1) generated in the switched-capacitor circuit 20. The input terminals 331 through 336 are respectively connected to the output terminals 203 through 208 of the switched-capacitor circuit 20 at the outside of the supply modulator 33 and are respectively connected to the switches S531 through S536 at the inside of the supply modulator 33.

The output terminal 337 is an example of a third output terminal and is a terminal for selectively supplying at least one of the discrete voltages to the power amplifier 2c. The output terminal 337 is connected to the power amplifier 2c at the outside of the supply modulator 33 and is connected to the switches S531 through S536 at the inside of the supply modulator 33.

The switch S531 is an example of a thirteenth switch and is connected between the input terminal 331 and the output terminal 337. With this connection configuration, as a result of the opening/closing of the switch S531 being changed by a control signal from the digital control circuit 60, the switch S531 can selectively connect the input terminal 331 to the output terminal 337 or disconnect the input terminal 331 from the output terminal 337.

The switch S532 is an example of a fourteenth switch and is connected between the input terminal 332 and the output terminal 337. With this connection configuration, as a result of the opening/closing of the switch S532 being changed by a control signal from the digital control circuit 60, the switch S532 can selectively connect the input terminal 332 to the output terminal 337 or disconnect the input terminal 332 from the output terminal 337.

The switch S533 is connected between the input terminal 333 and the output terminal 337. With this connection configuration, as a result of the opening/closing of the switch S533 being changed by a control signal from the digital control circuit 60, the switch S533 can selectively connect the input terminal 333 to the output terminal 337 or disconnect the input terminal 333 from the output terminal 337.

The switch S534 is connected between the input terminal 334 and the output terminal 337. With this connection configuration, as a result of the opening/closing of the switch S534 being changed by a control signal from the digital control circuit 60, the switch S534 can selectively connect the input terminal 334 to the output terminal 337 or disconnect the input terminal 334 from the output terminal 337.

The switch S535 is connected between the input terminal 335 and the output terminal 337. With this connection configuration, as a result of the opening/closing of the switch S535 being changed by a control signal from the digital control circuit 60, the switch S535 can selectively connect the input terminal 335 to the output terminal 337 or disconnect the input terminal 335 from the output terminal 337.

The switch S536 is connected between the input terminal 336 and the output terminal 337. With this connection configuration, as a result of the opening/closing of the switch S536 being changed by a control signal from the digital control circuit 60, the switch S536 can selectively connect the input terminal 336 to the output terminal 337 or disconnect the input terminal 336 from the output terminal 337.

In the exemplary embodiment, the switches S531 through S536 are controlled to be ON mutually exclusively. That is, the switches S531 through S536 are controlled such that only one of them is closed and the remaining switches are all opened. With this configuration, the supply modulator 33 can selectively connect one of the output terminals 203 through 208 of the switched-capacitor circuit 20 to the power amplifier 2c and supply the selected one of the discrete voltages (V1 through V6) to the power amplifier 2c.

The configuration of the supply modulator 33 shown in FIG. 5C is only an example and is not intended to limit the configuration of the supply modulator 33. Among others, the switches S531 through S536 may be configured and controlled in any manner when they can selectively connect at least one of the six input terminals 331 through 336 to the output terminal 337. For example, two of the switches S531 through S536 may be closed, and the remaining four of the switches S531 through S536 may be opened.

### [5. Circuit Configuration of Digital Control Circuit 60]

The circuit configuration of the digital control circuit 60 will now be described below with reference to FIG. 6. FIG. 6 is a circuit diagram of the digital control circuit 60 according to the exemplary embodiment.

The circuit configuration shown in FIG. 6 is only an example. The digital control circuit 60 can be implemented by using any of a variety of circuit implementations and circuit technologies. Hence, the following explanation of the digital control circuit 60 is not to be interpreted in a limited manner.

The digital control circuit 60 includes a first controller 61, a second controller 62, and control terminals 601 through 605.

The first controller 61 can process a serial data signal supplied from the RFIC 5 via the control terminals 601 and 602 so as to generate a control signal for controlling the pre-regulator circuit 10 and the switched-capacitor circuit 20. The first controller 61 can also process serial data signals to generate control signals for controlling the supply modulators 31 through 33 in the APT mode. As a serial data signal, a source-synchronous digital control signal, for example, is used. As a serial data signal, a clock-embedded digital control signal may be used. The opening/closing of the switches included in the pre-regulator circuit 10 and those in the switched-capacitor circuit 20 is controlled by the control signal from the first controller 61. In the APT mode, the opening/closing of the switches included in the supply modulators 31 through 33 is also controlled by the control signal from the first controller 61.

In the exemplary embodiment, the same set of a clock signal and a data signal is used for the pre-regulator circuit 10 and the switched-capacitor circuit 20. However, this is only an example. For instance, one set of a clock signal and a data signal may be used for the pre-regulator circuit 10, and another set of a clock signal and a data signal may be used for the switched-capacitor circuit 20.

In the D-ET mode, the second controller 62 processes parallel data signals supplied from the RFIC 5 via the control terminals 603 through 605 so as to generate control signals for controlling the supply modulators 31 through 33. As the parallel data signals, digital control level (DCL) signals (DCL1 through DCL3), for example, are used. The DCL signals (DCL1 through DCL3) are generated by the RFIC 5 based on envelope signals of radio-frequency signals to be amplified by the power amplifiers 2a through 2c. The opening/closing of the switches included in the supply modulators 31 through 33 is controlled by the control signals from the second controller 62.

Each of the DCL signals (DCL1 through DCL3) is constituted by three one-bit signals. The voltages V1 through V6 are each represented by a combination of three one-bit signals. For example, V1 through V6 are represented by “000”, “001”, “010”, “011”, “100”, and “101”, respectively. For the representation for the voltage level, gray code may be used.

### [6. Implementation Example of Communication Device 7]

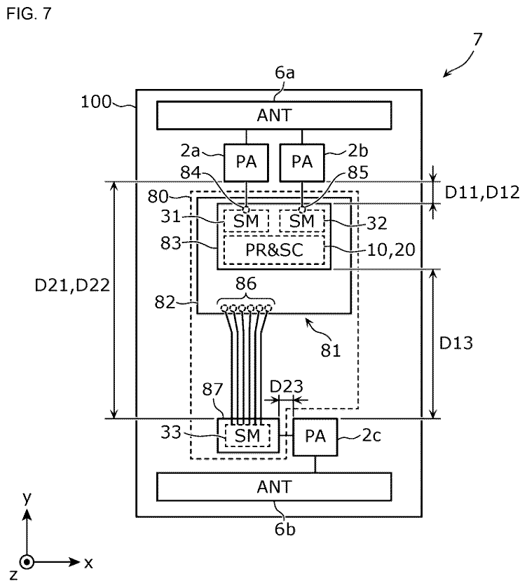

An implementation example of the communication device 7 will be described below with reference to FIG. 7. FIG. 7 illustrates an implementation example of the communication device 7 according to the exemplary embodiment. To easily understand the positional relationships between multiple circuit components in FIG. 7, the abbreviations of the functions of circuit components (“ANT” and “PA”, for example) are appended to the circuit components. However, such abbreviations may be omitted from actual circuit components. In FIG. 7, some of the components (filters 3a through 3c and RFIC 5, for example) shown in the circuit diagram in FIG. 2 are not shown.

The implementation example shown in FIG. 7 is only an example. The communication device 7 can be implemented by using any of a variety of circuit implementations and circuit technologies. Hence, the following explanation of the implementation example of the communication device 7 is not to be interpreted in a limited manner.

As illustrated in FIG. 7, in or on a mother substrate 100 of the communication device 7, the power amplifiers 2a through 2c (PA), a tracker system 80 including a tracker module 81 and an integrated circuit 87, a primary antenna 6a (ANT), and a secondary antenna 6b (ANT) are disposed.

The tracker module 81 includes a module laminate 82, an integrated circuit 83, and external connection terminals 84 through 86.

The integrated circuit 83 is an example of a first integrated circuit and is disposed in or on the module laminate 82. The integrated circuit 83 contains the switches included in the pre-regulator circuit 10 and in the switched-capacitor circuit 20 (PR&SC) and those in the supply modulators 31 and 32 (SM). The integrated circuit 83 is not limited to a single integrated circuit (chip) and may be divided into multiple integrated circuits.

The external connection terminal 84 is an example of a first external connection terminal and is disposed in or on the module laminate 82. The external connection terminal 84 is electrically connected to the power amplifier 2a at the outside of the tracker module 81 and is electrically connected to the output terminal 317 of the supply modulator 31 at the inside of the tracker module 81. With this configuration, at least one of multiple discrete voltages is selectively output from the supply modulator 31 to the external connection terminal 84.

The external connection terminal 85 is an example of a second external connection terminal and is disposed in or on the module laminate 82. The external connection terminal 85 is electrically connected to the power amplifier 2b at the outside of the tracker module 81 and is electrically connected to the output terminal 327 of the supply modulator 32 at the inside of the tracker module 81. With this configuration, at least one of multiple discrete voltages is selectively output from the supply modulator 32 to the external connection terminal 85.

The external connection terminals 86 are an example of multiple third external connection terminals and are disposed in or on the module laminate 82. The external connection terminals 86 are electrically connected to the integrated circuit 87 at the outside of the tracker module 81 and are electrically connected to the respective output terminals 203 through 208 of the switched-capacitor circuit 20 at the inside of the tracker module 81. With this configuration, multiple discrete voltages (V1 through V6) are output from the switched-capacitor circuit 20 to the external connection terminals 86.

The integrated circuit 87 is an example of a second integrated circuit and is disposed in or on the mother substrate 100 so as to be separate from the module laminate 82. The integrated circuit 87 contains the switches included in the supply modulator 33 (SM). The integrated circuit 87 is not limited to a single integrated circuit (chip) and may be divided into multiple integrated circuits.

The primary antenna 6a and the secondary antenna 6b are disposed along two sides of the mother substrate 100 to oppose each other. The primary antenna 6a and the secondary antenna 6b may be disposed so as to be separate from the mother substrate 100, instead of being disposed in or on the mother substrate 100.

The power amplifier 2a is an example of a first power amplifier and is disposed near the primary antenna 6a. The power amplifier 2a is disposed closer to the integrated circuit 83 than the power amplifier 2c is. That is, the distance D11 between the integrated circuit 83 and the power amplifier 2a is shorter than the distance D13 between the integrated circuit 83 and the power amplifier 2c (D11<D13).

The power amplifier 2b is an example of a second power amplifier and is disposed near the primary antenna 6a. The power amplifier 2b is disposed closer to the integrated circuit 83 than the power amplifier 2c is. That is, the distance D12 between the integrated circuit 83 and the power amplifier 2b is shorter than the distance D13 between the integrated circuit 83 and the power amplifier 2c (D12<D13).

The power amplifier 2c is an example of a third power amplifier and is disposed near the secondary antenna 6b. The power amplifier 2c is disposed closer to the integrated circuit 87 than the power amplifier 2a is. That is, the distance D23 between the integrated circuit 87 and the power amplifier 2c is shorter than the distance D21 between the integrated circuit 87 and the power amplifier 2a (D23<D21). The power amplifier 2c is disposed closer to the integrated circuit 87 than the power amplifier 2b is. That is, the distance D23 between the integrated circuit 87 and the power amplifier 2c is shorter than the distance D22 between the integrated circuit 87 and the power amplifier 2b (D23<D22).

The implementation example of the communication device 7 shown in FIG. 7 is only an example and is not intended to limit the implementation of the communication device 7. For example, the power amplifiers 2a and 2b may be integrated in one module or be mounted on one integrated circuit. All or some of the capacitors included in the pre-regulator circuit 10 and the switched-capacitor circuit 20 may be included in the tracker module 81 and be disposed in or on the module laminate 82. The power inductor L71 of the pre-regulator circuit 10 may be included in the tracker module 81 and be disposed in or on the module laminate 82. Alternatively, the power inductor L71 may be disposed in or on the mother substrate 100 so as to be separate from the module laminate 82.

### [7. Voltage Supply Method]

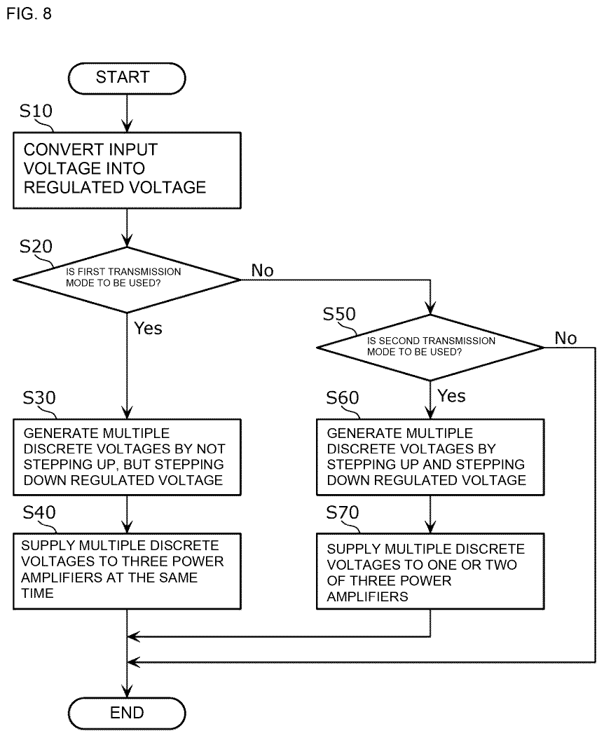

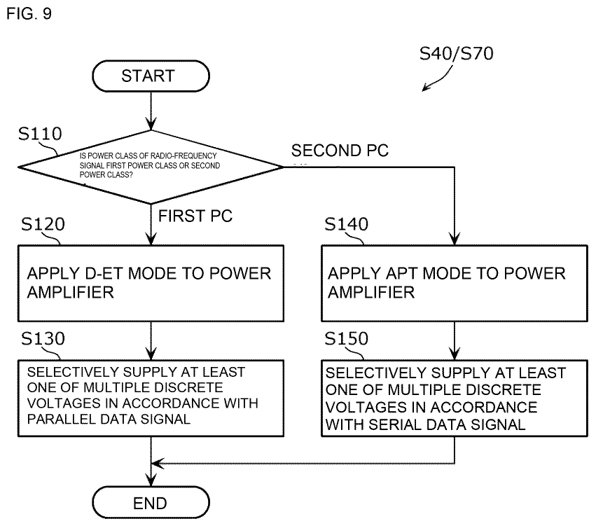

The voltage supply method according to the exemplary embodiment will now be described below with reference to FIGS. 8 and 9. FIGS. 8 and 9 are flowcharts illustrating the voltage supply method according to the exemplary embodiment.

An overview of the voltage supply method will first be discussed below with reference to FIG. 8 The pre-regulator circuit 10 converts an input voltage into a regulated voltage (S10). It is then determined whether a first transmission mode is to be used (S20). The first transmission mode is a mode for simultaneously transmitting three transmission signals. In the first transmission mode, voltages are supplied from the three supply modulators 31 through 33 to the three power amplifiers 2a through 2c, respectively, at the same time, and the three power amplifiers 2a through 2c operate simultaneously.

In an exemplary aspect, when the first transmission mode is to be used (Yes in S20), the switched-capacitor circuit 20 generates multiple discrete voltages by not stepping up, but stepping down the regulated voltage (S30). That is, in the pre-regulator circuit 10, the switch S73 is closed and the switch S74 is opened, so that the regulated voltage is applied to the node N6 of the switched-capacitor circuit 20. The supply modulators 31 through 33 respectively supply multiple discrete voltages to the three power amplifiers 2a through 2c at the same time (S40). That is, the supply modulators 31 through 33 respectively select at least one of the discrete voltages and supply the selected voltages to the power amplifiers 2a through 2c, independently of each other.

In contrast, when the first transmission mode is not to be used (No in S20), it is determined whether a second transmission mode is to be used (S50). The second transmission mode is a mode for transmitting one transmission signal or simultaneously transmitting two transmission signals. In the second transmission mode, a voltage is supplied from one or two of the three supply modulators 31 through 33 to one or two of the three power amplifiers 2a through 2c, and one or two of the power amplifiers 2a through 2c are operated. To put it conversely, in the second transmission mode, no voltage is supplied from one or two of the three supply modulators 31 through 33 to one or two of the three power amplifiers 2a through 2c, and one or two of the power amplifiers 2a through 2c are not operated. That is, in the second transmission mode, a voltage is supplied from one or two of the three supply modulators 31 through 33, while no voltage is supplied from the remaining one or two of the three supply modulators 31 through 33.

In an exemplary aspect, when the second transmission mode is to be used (Yes in S50), the switched-capacitor circuit 20 generates multiple discrete voltages by stepping up and stepping down the regulated voltage (S60). That is, in the pre-regulator circuit 10, the switch S74 is closed and the switch S73 is opened, so that the regulated voltage is applied to the node N5 of the switched-capacitor circuit 20. One or two of the supply modulators 31 through 33 supply discrete voltages to one or two of the three power amplifiers 2a through 2c (S70).

In an exemplary aspect, when the second transmission mode is not to be used (No in S50), the processing is terminated.

Details of steps S40 and S70 will be discussed below with reference to FIG. 9. The flowchart of FIG. 9 is executed for each of the power amplifiers 2a through 2c. It is first determined whether the power class of a radio-frequency signal to be amplified by a power amplifier is a first power class or a second power class (S110).

The power class is the classification of output power of a device, which is determined by the maximum output power of the device. As the value of the power class is smaller, the maximum output power is higher. For example, 3GPP (registered trademark) defines the values of the maximum output power of the individual power classes as follows: power class 1 is 31 dBm; power class 1.5 is 29 dBm; power class 2 is 26 dBm; power class 3 is 23 dBm; and power class 5 is 20 dBm.

The maximum output power of a device is determined by the maximum output power at the end portion of an antenna of the device. The maximum output power of UE is measured by a method defined by 3GPP (registered trademark), for example. For instance, in FIG. 2, the maximum output power of the communication device 7 can be determined by measuring radiation power of the primary antenna 6a or the secondary antenna 6b. Instead of measuring radiation power, the maximum output power of the primary antenna 6a or the secondary antenna 6b may be measured by using a measurement instrument (such as a spectrum analyzer) connected to a terminal provided near the primary antenna 6a or the secondary antenna 6b.

The first power class is a power class determined by first maximum output power. The second power class is a power class determined by second maximum output power. The first maximum output power is higher than the second maximum output power. For example, when the first maximum output power is 26 dBm and the second maximum output power is 23 dBm, the first power class corresponds to power class 2, while the second power class corresponds to power class 3.

In an exemplary aspect, when a radio-frequency signal having the first power class is to be amplified by a power amplifier (first PC in S110), the D-ET mode is applied to this power amplifier (S120). The supply modulator selectively supplies at least one of multiple discrete voltages to the power amplifier in accordance with a parallel data signal (S130). More specifically, when a radio-frequency signal having the first power class is to be amplified by the power amplifier 2a, the D-ET mode is applied to the power amplifier 2a, and the supply modulator 31 selectively supplies at least one of the discrete voltages to the power amplifier 2a in accordance with a first parallel data signal. In an exemplary aspect, when a radio-frequency signal having the first power class is to be amplified by the power amplifier 2b, the D-ET mode is applied to the power amplifier 2b, and the supply modulator 32 selectively supplies at least one of the discrete voltages to the power amplifier 2b in accordance with a second parallel data signal. In an exemplary aspect, when a radio-frequency signal having the first power class is to be amplified by the power amplifier 2c, the D-ET mode is applied to the power amplifier 2c, and the supply modulator 33 selectively supplies at least one of the discrete voltages to the power amplifier 2c in accordance with a third parallel data signal.

In contrast, when a radio-frequency signal having the second power class is to be amplified by a power amplifier (second PC in S110), the APT mode is applied to this power amplifier (S140). The supply modulator selectively supplies at least one of multiple discrete voltages to the power amplifier in accordance with a serial data signal (S150). More specifically, when a radio-frequency signal having the second power class is to be amplified by the power amplifier 2a, the APT mode is applied to the power amplifier 2a, and the supply modulator 31 selectively supplies at least one of the discrete voltages to the power amplifier 2a in accordance with a first serial data signal. In an exemplary aspect, when a radio-frequency signal having the second power class is to be amplified by the power amplifier 2b, the APT mode is applied to the power amplifier 2b, and the supply modulator 32 selectively supplies at least one of the discrete voltages to the power amplifier 2b in accordance with a second serial data signal. In an exemplary aspect, when a radio-frequency signal having the second power class is to be amplified by the power amplifier 2c, the APT mode is applied to the power amplifier 2c, and the supply modulator 33 selectively supplies at least one of the discrete voltages to the power amplifier 2c in accordance with a third serial data signal.

### [8. Technical Effects and Others]

As described above, the tracker system 80 according to the exemplary embodiment includes a module laminate 82, an integrated circuit 83 disposed in or on the module laminate 82, and an integrated circuit 87 disposed so as to be separate from the module laminate 82. The integrated circuit 83 includes at least one switch included in a switched-capacitor circuit 20, at least one switch included in a supply modulator 31, and at least one switch included in a supply modulator 32. The integrated circuit 87 includes at least one switch included in a supply modulator 33. The switched-capacitor circuit 20 generates multiple discrete voltages. The supply modulator 31 selectively outputs at least one of the multiple discrete voltages to a power amplifier 2a connected to a primary antenna 6a. The supply modulator 32 selectively outputs at least one of the multiple discrete voltages to a power amplifier 2b connected to the primary antenna 6a. The supply modulator 33 selectively outputs at least one of the multiple discrete voltages to a power amplifier 2c connected to a secondary antenna 6b.

With this configuration, multiple discrete voltages generated by the single switched-capacitor circuit 20 can be output to the three supply modulators 31 through 33. This allows the three supply modulators 31 through 33 to select voltages and supply the selected voltages to the three power amplifiers 2a through 2c, independently of each other. That is, a discrete voltage generating circuit for the three power amplifiers 2a through 2c can be implemented by the single switched-capacitor circuit 20, thereby reducing the size of the tracker module 81. Additionally, the integrated circuit 83 including the switches of the supply modulators 31 and 32, which are used for supplying voltages to the power amplifiers 2a and 2b connected to the primary antenna 6a, is disposed in or on the module laminate 82, while the integrated circuit 87 including the switches of the supply modulator 83, which is used for supplying a voltage to the power amplifier 2c connected to the secondary antenna 6b, is disposed so as to be separate from the module laminate 82. This can increase the flexibility in the arrangement of the integrated circuit 87 (supply modulator 33), thereby suppressing the degradation of the voltages to be supplied to the power amplifiers 2a through 2c.

In one example, in the tracker system 80 according to the exemplary embodiment, the power amplifier 2a may be disposed closer to the integrated circuit 83 than the power amplifier 2c is.

With this configuration, the integrated circuit 83 including the switches of the supply modulator 31 can be disposed near the power amplifier 2a, thereby decreasing the length of wiring between the supply modulator 31 and the power amplifier 2a. This can suppress the degradation of a voltage supplied from the supply modulator 31 to the power amplifier 2a. In particular, when the D-ET mode is applied to the power amplifier 2a, the voltage is discretely varied at higher speed, and the decreased length of wiring can thus suppress the degradation of a supply voltage effectively.

In one example, in the tracker system 80 according to the exemplary embodiment, the power amplifier 2b may be disposed closer to the integrated circuit 83 than the power amplifier 2c is.

With this configuration, the integrated circuit 83 including the switches of the supply modulator 32 can be disposed near the power amplifier 2b, thereby decreasing the length of wiring between the supply modulator 32 and the power amplifier 2b. This can suppress the degradation of a voltage supplied from the supply modulator 32 to the power amplifier 2b. In particular, when the D-ET mode is applied to the power amplifier 2b, the voltage is discretely varied at higher speed, and the decreased length of wiring can thus suppress the degradation of a supply voltage effectively.

In one example, in the tracker system 80 according to the exemplary embodiment, the power amplifier 2c may be disposed closer to the integrated circuit 87 than the power amplifier 2a is.

With this configuration, the integrated circuit 87 including the switches of the supply modulator 33 can be disposed near the power amplifier 2c, thereby decreasing the length of wiring between the supply modulator 33 and the power amplifier 2c. This can suppress the degradation of a voltage supplied from the supply modulator 33 to the power amplifier 2c. In particular, when the D-ET mode is applied to the power amplifier 2c, the voltage is discretely varied at higher speed, and the decreased length of wiring can thus suppress the degradation of a supply voltage effectively.

In one example, in the tracker system 80 according to the exemplary embodiment, the power amplifier 2c may be disposed closer to the integrated circuit 87 than the power amplifier 2b is.

With this configuration, the integrated circuit 87 including the switches of the supply modulator 33 can be disposed near the power amplifier 2c, thereby decreasing the length of wiring between the supply modulator 33 and the power amplifier 2c. This can suppress the degradation of a voltage supplied from the supply modulator 33 to the power amplifier 2c. In particular, when the D-ET mode is applied to the power amplifier 2c, the voltage is discretely varied at higher speed, and the decreased length of wiring can thus suppress the degradation of a supply voltage effectively.

In one example, in the tracker system 80 according to the exemplary embodiment, when a radio-frequency signal having a first power class, which is determined by first maximum output power, is to be amplified by the power amplifier 2a, the D-ET mode may be applied to the power amplifier 2a. When a radio-frequency signal having a second power class, which is determined by second maximum output power lower than the first maximum output power, is to be amplified by the power amplifier 2a, the APT mode may be applied to the power amplifier 2a.

With this configuration, when a radio-frequency signal having the first power class, which has higher maximum output power, is to be amplified by the power amplifier 2a, the D-ET mode is applied to the power amplifier 2a. Accordingly, when the power consumption is expected to be reduced by a greater amount by the improved power-added efficiency, the D-ET mode can be applied, thereby achieving effective power consumption.

In one example, in the tracker system 80 according to the exemplary embodiment, when a radio-frequency signal having the first power class is to be amplified by the power amplifier 2b, the D-ET mode may be applied to the power amplifier 2b. When a radio-frequency signal having the second power class is to be amplified by the power amplifier 2b, the APT mode may be applied to the power amplifier 2b.

With this configuration, when a radio-frequency signal having the first power class, which has higher maximum output power, is to be amplified by the power amplifier 2b, the D-ET mode is applied to the power amplifier 2b. Accordingly, when the power consumption is expected to be reduced by a greater amount by the improved power-added efficiency, the D-ET mode can be applied, thereby achieving effective power consumption.

In one example, in the tracker system 80 according to the exemplary embodiment, when a radio-frequency signal having the first power class is to be amplified by the power amplifier 2c, the D-ET mode may be applied to the power amplifier 2c. When a radio-frequency signal having the second power class is to be amplified by the power amplifier 2c, the APT mode may be applied to the power amplifier 2c.

With this configuration, when a radio-frequency signal having the first power class, which has higher maximum output power, is to be amplified by the power amplifier 2c, the D-ET mode is applied to the power amplifier 2c. Accordingly, when the power consumption is expected to be reduced by a greater amount by the improved power-added efficiency, the D-ET mode can be applied, thereby achieving effective power consumption.

In one example, in the tracker system 80 according to the exemplary embodiment, when a radio-frequency signal having the first power class, which is determined by first maximum output power, is to be amplified by the power amplifier 2a, the supply modulator 31 may selectively output at least one of multiple discrete voltages to the power amplifier 2a in accordance with a parallel data signal. When a radio-frequency signal having a second power class, which is determined by second maximum output power lower than the first maximum output power, is to be amplified by the power amplifier 2a, the supply modulator 31 may selectively output at least one of multiple discrete voltages to the power amplifier 2a in accordance with a serial data signal.

With this configuration, when a radio-frequency signal having the first power class, which has higher maximum output power, is to be amplified by the power amplifier 2a, a parallel data signal controls the supply modulator 31 so that multiple discrete voltages can be switched at high speed. This can supply the voltage suitable for the instantaneous power of the radio-frequency signal to the power amplifier 2a and thus to improve the power-added efficiency of the power amplifier 2a in accordance with the first power class of the radio-frequency signal, thereby achieving effective power consumption.

In one example, in the tracker system 80 according to the exemplary embodiment, when a radio-frequency signal having the first power class is to be amplified by the power amplifier 2b, the supply modulator 32 may selectively output at least one of multiple discrete voltages to the power amplifier 2b in accordance with a parallel data signal. When a radio-frequency signal having the second power class is to be amplified by the power amplifier 2b, the supply modulator 32 may selectively output at least one of multiple discrete voltages to the power amplifier 2b in accordance with a serial data signal.

With this configuration, when a radio-frequency signal having the first power class, which has higher maximum output power, is to be amplified by the power amplifier 2b, a parallel data signal controls the supply modulator 32 so that multiple discrete voltages can be switched at high speed. This can supply the voltage suitable for the instantaneous power of the radio-frequency signal to the power amplifier 2b and thus to improve the power-added efficiency of the power amplifier 2b in accordance with the first power class of the radio-frequency signal, thereby achieving effective power consumption.

In one example, in the tracker system 80 according to the exemplary embodiment, when a radio-frequency signal having the first power class is to be amplified by the power amplifier 2c, the supply modulator 33 may selectively output at least one of multiple discrete voltages to the power amplifier 2c in accordance with a parallel data signal. When a radio-frequency signal having the second power class is to be amplified by the power amplifier 2c, the supply modulator 33 may selectively output at least one of multiple discrete voltages to the power amplifier 2c in accordance with a serial data signal.

With this configuration, when a radio-frequency signal having the first power class, which has higher maximum output power, is to be amplified by the power amplifier 2c, a parallel data signal controls the supply modulator 33 so that multiple discrete voltages can be switched at high speed. This can supply the voltage suitable for the instantaneous power of the radio-frequency signal to the power amplifier 2c and thus to improve the power-added efficiency of the power amplifier 2c in accordance with the first power class of the radio-frequency signal, thereby achieving effective power consumption.

In one example, in the tracker system 80 according to the exemplary embodiment, in a first transmission mode in which the power amplifiers 2a through 2c operate simultaneously, the switched-capacitor circuit 20 may generate multiple discrete voltages not by stepping up a regulated voltage but by stepping down the regulated voltage. In a second transmission mode in which one of the power amplifiers 2a through 2c operates and the remaining two of the power amplifiers 2a through 2c do not operate or two of the power amplifiers 2a through 2c operate and the remaining one of the power amplifiers 2a through 2c does not operate, the switched-capacitor circuit 20 may generate multiple discrete voltages by stepping up and stepping down the regulated voltage.

In the first transmission mode (3Tx) in which the three power amplifiers 2a through 2c operate at the same time to simultaneously transmit three radio-frequency signals, the switched-capacitor circuit 20 generates multiple discrete voltages by stepping down a regulated voltage instead of stepping it up. Compared with the second transmission mode (1Tx/2Tx) in which only one of the three power amplifiers 2a through 2c is operated to transmit only one radio-frequency signal or two of the three power amplifiers 2a through 2c are operated to simultaneously transmit two radio-frequency signals, in 3Tx, the output power peak of each of the three power amplifiers 2a through 2c is likely to become lower, and the time for supplying the highest voltage of multiple discrete voltages (that is, the frequency of occurrence with which the highest voltage is supplied) to the three power amplifiers 2a through 2c is likely to increase. In 3Tx, therefore, the switched-capacitor circuit 20 generates multiple discrete voltages not by stepping up the regulated voltage (which is equal to the highest voltage) but by stepping it down. This makes it possible to suppress a voltage drop in the highest voltage, which is more frequently supplied, and thus to improve the stability of the supply voltage. In 2Tx/1Tx, the switched-capacitor circuit 20 generates multiple discrete voltages by stepping up and stepping down the regulated voltage (which is not equal to the highest voltage). This makes it possible to suppress a voltage drop in the voltage, which is more frequently supplied and is lower than the highest voltage, and thus to improve the stability of the supply voltage.

The tracker module 81 according to the exemplary embodiment includes a module laminate 82, at least one integrated circuit 83 disposed in or on the module laminate 82, and external connection terminals 84 through 86 disposed in or on the module laminate 82. The at least one integrated circuit 83 includes at least one switch included in a switched-capacitor circuit 20, at least one switch included in a supply modulator 31, and at least one switch included in a supply modulator 32. The switched-capacitor circuit 20 generates multiple discrete voltages and outputs the generated discrete voltages to the supply modulators 31 and 32 and the multiple external connection terminals 86. The supply modulator 31 selectively outputs at least one of the discrete voltages to the external connection terminal 84. The supply modulator 32 selectively outputs at least one of the discrete voltages to the external connection terminal 85. The external connection terminal 84 is connected to a power amplifier 2a connected to a primary antenna 6a. The external connection terminal 85 is connected to a power amplifier 2b connected to the primary antenna 6a. The external connection terminals 86 are selectively connected to a power amplifier 2c connected to a secondary antenna 6b.

With this configuration, multiple discrete voltages generated by the single switched-capacitor circuit 20 can be output to the two supply modulators 31 and 32 within the tracker module 81 and also output to the supply modulator 33 outside the tracker module 81 via the external connection terminals 86. Hence, a discrete voltage generating circuit for the three power amplifiers 2a through 2c can be implemented by the single switched-capacitor circuit 20, thereby reducing the size of the tracker module 81. Additionally, the tracker module 81 can be connected to the supply modulator 33, which is used for supplying a voltage to the power amplifier 2c connected to the secondary antenna 6b, via the external connection terminals 86. The supply modulator 33 can thus be excluded from the tracker module 81. This can increase the flexibility in the arrangement of the supply modulator 33, thereby suppressing the degradation of the voltages to be supplied to the power amplifiers 2a through 2c.

In one example, in the tracker module 81 according to the exemplary embodiment, when a radio-frequency signal having a first power class, which is determined by first maximum output power, is to be amplified by the power amplifier 2a, the D-ET mode may be applied to the power amplifier 2a. When a radio-frequency signal having a second power class, which is determined by second maximum output power lower than the first maximum output power, is to be amplified by the power amplifier 2a, the APT mode may be applied to the power amplifier 2a.

With this configuration, when a radio-frequency signal having the first power class, which has higher maximum output power, is to be amplified by the power amplifier 2a, the D-ET mode is applied to the power amplifier 2a. Accordingly, when the power consumption is expected to be reduced by a greater amount by the improved power-added efficiency, the D-ET mode can be applied, thereby achieving effective power consumption.

In one example, in the tracker module 81 according to the exemplary embodiment, when a radio-frequency signal having the first power class is to be amplified by the power amplifier 2b, the D-ET mode may be applied to the power amplifier 2b. When a radio-frequency signal having the second power class is to be amplified by the power amplifier 2b, the APT mode may be applied to the power amplifier 2b.

With this configuration, when a radio-frequency signal having the first power class, which has higher maximum output power, is to be amplified by the power amplifier 2b, the D-ET mode is applied to the power amplifier 2b. Accordingly, when the power consumption is expected to be reduced by a greater amount by the improved power-added efficiency, the D-ET mode can be applied, thereby achieving effective power consumption.

In one example, in the tracker module 81 according to the exemplary embodiment, when a radio-frequency signal having the first power class, which is determined by first maximum output power, is to be amplified by the power amplifier 2a, the supply modulator 31 may selectively output at least one of multiple discrete voltages to the external connection terminal 84 in accordance with a parallel data signal. When a radio-frequency signal having a second power class, which is determined by second maximum output power lower than the first maximum output power, is to be amplified by the power amplifier 2a, the supply modulator 31 may selectively output at least one of multiple discrete voltages to the external connection terminal 84 in accordance with a serial data signal.

With this configuration, when a radio-frequency signal having the first power class, which has higher maximum output power, is to be amplified by the power amplifier 2a, a parallel data signal controls the supply modulator 31 so that multiple discrete voltages can be switched at high speed. This can supply the voltage suitable for the instantaneous power of the radio-frequency signal to the power amplifier 2a and thus to improve the power-added efficiency of the power amplifier 2a in accordance with the first power class of the radio-frequency signal, thereby achieving effective power consumption.

In one example, in the tracker module 81 according to the exemplary embodiment, when a radio-frequency signal having the first power class is to be amplified by the power amplifier 2b, the supply modulator 32 may selectively output at least one of multiple discrete voltages to the external connection terminal 85 in accordance with a parallel data signal. When a radio-frequency signal having the second power class is to be amplified by the power amplifier 2b, the supply modulator 32 may selectively output at least one of multiple discrete voltages to the external connection terminal 85 in accordance with a serial data signal.

With this configuration, when a radio-frequency signal having the first power class, which has higher maximum output power, is to be amplified by the power amplifier 2b, a parallel data signal controls the supply modulator 32 so that multiple discrete voltages can be switched at high speed. This can supply the voltage suitable for the instantaneous power of the radio-frequency signal to the power amplifier 2b and thus to improve the power-added efficiency of the power amplifier 2b in accordance with the first power class of the radio-frequency signal, thereby achieving effective power consumption.

In one example, in the tracker module 81 according to the exemplary embodiment, in a first transmission mode in which the power amplifiers 2a through 2c operate simultaneously, the switched-capacitor circuit 20 may generate multiple discrete voltages not by stepping up a regulated voltage but by stepping down the regulated voltage. In a second transmission mode in which one of the power amplifiers 2a through 2c operates and the remaining two of the power amplifiers 2a through 2c do not operate or two of the power amplifiers 2a through 2c operate and the remaining one of the power amplifiers 2a through 2c does not operate, the switched-capacitor circuit 20 may generate multiple discrete voltages by stepping up and stepping down the regulated voltage.

In the first transmission mode (3Tx) in which the three power amplifiers 2a through 2c operate at the same time to simultaneously transmit three radio-frequency signals, the switched-capacitor circuit 20 generates multiple discrete voltages by stepping down a regulated voltage instead of stepping it up. Compared with the second transmission mode (1Tx/2Tx) in which only one of the three power amplifiers 2a through 2c is operated to transmit only one radio-frequency signal or two of the three power amplifiers 2a through 2c are operated to simultaneously transmit two radio-frequency signals, in 3Tx, the output power peak of each of the three power amplifiers 2a through 2c is likely to become lower, and the time for supplying the highest voltage of multiple discrete voltages (that is, the frequency of occurrence with which the highest voltage is supplied) to the three power amplifiers 2a through 2c is likely to increase. In 3Tx, therefore, the switched-capacitor circuit 20 generates multiple discrete voltages not by stepping up the regulated voltage (which is equal to the highest voltage) but by stepping it down. This makes it possible to suppress a voltage drop in the highest voltage, which is more frequently supplied, and thus to improve the stability of the supply voltage. In 2Tx/1Tx, the switched-capacitor circuit 20 generates multiple discrete voltages by stepping up and stepping down the regulated voltage (which is not equal to the highest voltage). This makes it possible to suppress a voltage drop in the voltage, which is more frequently supplied and is lower than the highest voltage, and thus to improve the stability of the supply voltage.

### ADDITIONAL EXEMPLARY EMBODIMENTS

The tracker system and the tracker module according to the present disclosure have been discussed above through illustration of the exemplary embodiment. However, the tracker system and the tracker module of the disclosure are not restricted to the above-described exemplary embodiment. Other exemplary embodiments implemented by combining certain elements in the above-described exemplary embodiment and other modified examples obtained by making various modifications to the above-described exemplary embodiment by those skilled in the art without departing from the scope and spirit of the disclosure are also encompassed in the disclosure. Various types of equipment integrating the above-described tracker system or the tracker module are also encompassed in the disclosure.

For example, in the circuit configurations of various circuits according to the exemplary embodiment, another circuit element and another wiring, for example, may be inserted onto a path connecting circuit elements or a path connecting signal paths illustrated in the drawings. For instance, an inductor and/or a capacitor may be inserted between the tracker circuit and a power amplifier.

The switched-capacitor circuit 20 according to the above-described exemplary embodiment generates six discrete voltages. However, the switched-capacitor circuit 20 is not limited to this configuration. For example, the switched-capacitor circuit 20 may generate five or less discrete voltages or seven or more discrete voltages.

In the switched-capacitor circuit 20 according to the above-described exemplary embodiment, the input terminal 202 is connected to the node N5. However, the node to which the input terminal 202 is connected is not limited to the node N5. For instance, the input terminal 202 may be connected to one of the nodes N4 through N1 instead of the node N5.

The exemplary aspects of the present disclosure can find widespread application in communication equipment, such as a mobile phone, as a tracker module and/or a tracker circuit that supplies a voltage to a power amplifier.

### REFERENCE SIGNS LIST

1 tracker circuit
2a, 2b, 2c power amplifier
3a, 3b, 3c filter
5 RFIC
6a primary antenna
6b secondary antenna
7 communication device
10 pre-regulator circuit
20 switched-capacitor circuit
31, 32, 33 supply modulator
50 DC power source
60 digital control circuit
61 first controller
62 second controller
80 tracker system
81 tracker module
82 module laminate
83, 87 integrated circuit
84, 85, 86 external connection terminal
101, 201, 202, 311, 312, 313, 314, 315, 316, 321, 322, 323, 324, 325, 326, 331, 332, 333, 334, 335, 336 input terminal
102, 103, 203, 204, 205, 206, 207, 208, 317, 327, 337 output terminal
601, 602, 603, 604, 605 control terminal

1. A tracker system comprising:
a module laminate;
at least one first integrated circuit in or on the module laminate; and
at least one second integrated circuit that is separate from the module laminate, wherein:
the at least one first integrated circuit includes at least one switch in a switched-capacitor circuit, at least one switch in a first supply modulator, and at least one switch in a second supply modulator,
the at least one second integrated circuit includes at least one switch in a third supply modulator,
the switched-capacitor circuit is configured to generate a plurality of discrete voltages,
the first supply modulator is configured to selectively output at least one discrete voltage of the plurality of discrete voltages to a first power amplifier that is connected to a primary antenna,
the second supply modulator is configured to selectively output at least one discrete voltage of the plurality of discrete voltages to a second power amplifier that is connected to the primary antenna, and
the third supply modulator is configured to selectively output at least one discrete voltage of the plurality of discrete voltages to a third power amplifier that is connected to a secondary antenna.

2. The tracker system according to claim 1, wherein the first power amplifier is disposed closer to the at least one first integrated circuit than the third power amplifier is.

3. The tracker system according to claim 1, wherein the second power amplifier is disposed closer to the at least one first integrated circuit than the third power amplifier is.

4. The tracker system according to claim 1, wherein the third power amplifier is disposed closer to the at least one second integrated circuit than the first power amplifier is.

5. The tracker system according to claim 1, wherein the third power amplifier is disposed closer to the at least one second integrated circuit than the second power amplifier is.

6. The tracker system according to claim 1, wherein:
when a radio-frequency signal to be amplified by the first power amplifier is of a first power class having a first maximum output power, a D-ET Digital Envelope Tracking (D-ET) mode is applied to the first power amplifier; and
when a radio-frequency signal to be amplified by the first power amplifier is of a second power class having a second maximum output power that is lower than the first maximum output power, an Average Power Tracking (APT) mode is applied to the first power amplifier.

7. The tracker system according to claim 6, wherein:
when a radio-frequency signal to be amplified by the second power amplifier is of the first power class, the D-ET mode is applied to the second power amplifier; and
when a radio-frequency signal to be amplified by the second power amplifier is of the second power class, the APT mode is applied to the second power amplifier.

8. The tracker system according to claim 6, wherein:
when a radio-frequency signal to be amplified by the third power amplifier is of the first power class, the D-ET mode is applied to the third power amplifier; and
when a radio-frequency signal to be amplified by the third power amplifier is of the second power class, the APT mode is applied to the third power amplifier.

9. The tracker system according to claim 1, wherein:
when a radio-frequency signal to be amplified by the first power amplifier is of a first power class having a first maximum output power, the first supply modulator is configured to selectively output at least one discrete voltage of the plurality of discrete voltages to the first power amplifier in accordance with a parallel data signal; and
when a radio-frequency signal to be amplified by the first power amplifier is of a second power class having a second maximum output power that is lower than the first maximum output power, the first supply modulator is configured to selectively output at least one discrete voltage of the plurality of discrete voltages to the first power amplifier in accordance with a serial data signal.

10. The tracker system according to claim 9, wherein:
when a radio-frequency signal to be amplified by the second power amplifier is of the first power class, the second supply modulator is configured to selectively output at least one discrete voltage of the plurality of discrete voltages to the second power amplifier in accordance with a parallel data signal; and
when a radio-frequency signal to be amplified by the second power amplifier is of the second power class, the second supply modulator is configured to selectively output at least one discrete voltage of the plurality of discrete voltages to the second power amplifier in accordance with a serial data signal.

11. The tracker system according to claim 9, wherein:
when a radio-frequency signal to be amplified by the third power amplifier is of the first power class, the third supply modulator is configured to selectively output at least one discrete voltage of the plurality of discrete voltages to the third power amplifier in accordance with a parallel data signal; and
when a radio-frequency signal to be amplified by the third power amplifier is of the second power class, the third supply modulator is configured to selectively output at least one discrete voltage of the plurality of discrete voltages to the third power amplifier in accordance with a serial data signal.

12. The tracker system according to claim 1, wherein:
in a first transmission mode in which the first power amplifier, the second power amplifier, and the third power amplifier operate simultaneously, the switched-capacitor circuit is configured to generate the plurality of discrete voltages by stepping down a regulated voltage, and
in a second transmission mode in which at least one power amplifier of the first power amplifier, the second power amplifier, and the third power amplifier does not operate, the switched-capacitor circuit is configured to generate the plurality of discrete voltages by stepping up and stepping down the regulated voltage.

13. A tracker module comprising:
a module laminate;
at least one integrated circuit in or on the module laminate; and
a first external connection terminal, a second external connection terminal, and a plurality of third external connection terminals that are in or on the module laminate, wherein:
the at least one integrated circuit includes at least one switch in a switched-capacitor circuit, at least one switch in a first supply modulator, and at least one switch in a second supply modulator,
the switched-capacitor circuit is configured to generate a plurality of discrete voltages and output the plurality of discrete voltages to the first supply modulator, the second supply modulator, and the plurality of third external connection terminals,
the first supply modulator is configured to selectively output at least one discrete voltage of the plurality of discrete voltages to the first external connection terminal,
the second supply modulator is configured to selectively output at least one discrete voltage of the plurality of discrete voltages to the second external connection terminal,
the first external connection terminal is connected to a first power amplifier that is connected to a primary antenna,
the second external connection terminal is connected to a second power amplifier that is connected to the primary antenna, and
the plurality of third external connection terminals are selectively connected to a third power amplifier that is connected to a secondary antenna.

14. The tracker module according to claim 13, wherein:
when a radio-frequency signal to be amplified by the first power amplifier is of a first power class having a first maximum output power, a D-ET mode is applied to the first power amplifier; and
when a radio-frequency signal to be amplified by the first power amplifier is of a second power class having a second maximum output power that is lower than the first maximum output power, an APT mode is applied to the first power amplifier.

15. The tracker module according to claim 14, wherein:
when a radio-frequency signal to be amplified by the second power amplifier is of the first power class, the D-ET mode is applied to the second power amplifier; and
when a radio-frequency signal to be amplified by the second power amplifier is of the second power class, the APT mode is applied to the second power amplifier.

16. The tracker module according to claim 13, wherein:
when a radio-frequency signal to be amplified by the first power amplifier is of a first power class having a first maximum output power, the first supply modulator is configured to selectively output at least one discrete voltage of the plurality of discrete voltages to the first external connection terminal in accordance with a parallel data signal; and
when a radio-frequency signal to be amplified by the first power amplifier is of a second power class having a second maximum output power that is lower than the first maximum output power, the first supply modulator is configured to selectively output at least one discrete voltage of the plurality of discrete voltages to the first external connection terminal in accordance with a serial data signal.

17. The tracker module according to claim 16, wherein:
when a radio-frequency signal to be amplified by the second power amplifier is of the first power class, the second supply modulator is configured to selectively output at least one discrete voltage of the plurality of discrete voltages to the second external connection terminal in accordance with a parallel data signal; and
when a radio-frequency signal to be amplified by the second power amplifier is of the second power class, the second supply modulator is configured to selectively output at least one discrete voltage of the plurality of discrete voltages to the second external connection terminal in accordance with a serial data signal.

18. The tracker module according to claim 13, wherein:
in a first transmission mode in which the first power amplifier, the second power amplifier, and the third power amplifier operate simultaneously, the switched-capacitor circuit is configured to generate the plurality of discrete voltages by stepping down a regulated voltage, and
in a second transmission mode in which at least one power amplifier of the first power amplifier, the second power amplifier, and the third power amplifier does not operate, the switched-capacitor circuit is configured to generate the plurality of discrete voltages by stepping up and stepping down the regulated voltage.

19. The tracker module according to claim 13, wherein the first power amplifier is disposed closer to the at least one integrated circuit than the third power amplifier is.

20. The tracker module according to claim 13, wherein the second power amplifier is disposed closer to the at least one integrated circuit than the third power amplifier is.
